(19) United States
(12) Patent Application Publication
(10) Pub. No.: US 2024/0222935 A1
(43) Pub. Date: Jul. 4, 2024

(54) Systems and Methods for Delivery of Light With Increased Omnidirectionality

(71) Applicants: The General Hospital Corporation, Boston, MA (US); Massachusetts Institute of Technology, Cambridge, MA (US)

(72) Inventors: Seok-Hyun Yun, Cambridge, MA (US); Paul Dannenberg, Boston, MA (US)

(21) Appl. No.: 17/905,806

(22) PCT Filed: Mar. 12, 2021
(86) PCT No.: PCT/US2021/022060

§ 371 Date: Sep. 7, 2022

Related U.S. Application Data
(60) Provisional application No. 62/989,665, filed on Mar. 14, 2020.
(60) Provisional application No. 63/123,788, filed on Dec. 10, 2020.

(51) Int. Cl. H01S 5/10

(52) U.S. Cl. CPC H01S 5/1075; H01S 5/1042; H01S 2301/18

(57) ABSTRACT

A laser microparticle for generating laser light with high omnidirectionality, including: an optical cavity including an active gain material capable of supporting one or more lasing cavity modes: and an optical scattering element which is incorporated into the optical cavity and configured to change a radiation pattern of the one or more lasing cavity modes to increase omnidirectionality of the radiation pattern, the size of the microparticle being less than 10 pm in each dimension.

### CROSS-REFERENCE TO RELATED APPLICATIONS

The present application is based on and claims priority from U.S. Patent Application Ser. No. 62/989,665, filed on Mar. 14, 2020, and U.S. Patent Application Ser. No. 63/123,788, filed on Dec. 10, 2020, the entire disclosures of which are incorporated herein by reference.

### STATEMENT REGARDING FEDERALLY SPONSORED RESEARCH

This invention was made with government support under DP1 EB024242 awarded by the National Institutes of Health. The government has certain rights in the invention.

### BACKGROUND

Laser particles (LPs) are micro- and nano-lasers in the form of particles dispersible in aqueous solution and are a new promising optical tool in the life sciences. Directional emission is notable feature of LPs and while this may be used to advantage in some applications, in general the directionality is considered a nuisance in many applications such as cellular labeling and tracking.

### SUMMARY

The ability to track individual cells in space over time is crucial to analyzing heterogeneous cell populations. Recently, microlaser particles have emerged as unique optical probes for massively multiplexed single-cell tagging. However, the microlaser's far-field emission is inherently direction-dependent and causes strong intensity fluctuations when the orientation of the particle varies randomly inside cells. Here, we demonstrate a general solution based on the incorporation of nanoscale light scatterers into the microlasers. Two schemes are developed by introducing either boundary defects or a scattering layer on microdisk lasers. The resulting laser output is omnidirectional, with the minimum-to-maximum ratio of angle-dependent intensity improved from 0.007 (−24 dB) to >0.23 (−6 dB). Transferred into live cells in vitro, omnidirectional laser particles within moving cells could be tracked continuously with high signal-to-noise ratios for two hours, while conventional microlasers exhibited frequent signal loss causing tracking failure.

Laser particles (LPs) are micro- and nano-lasers in the form of particles dispersible in aqueous solution. LPs are a new promising optical tool in the life sciences. In comparison to conventional photoluminescent probes such as fluorescent molecules, dye-doped microbeads, and gold nanoparticles, the laser emission from LPs has a few distinctive characteristics. The most striking feature is its narrow spectral bandwidth of <0.3 nm. This feature makes LPs an attractive choice for spectral multiplexing or fingerprinting of cells, so that individual cells can be tracked in in-vitro experiments, in a live animal, or across different single-cell analysis instruments, for example, from microscopy to single-cell sequencing. Recently, intracellular microdisk LPs were used to track 5,000 cells in a tumor spheroid, which can be scaled to millions or, in principle, billions of cells by harnessing multiple microdisks, where each has a distinctive spectral peak.

Directional emission is another notable feature of LPs. Just like conventional lasers, an LP relies on an optical cavity to confine and amplify light, and lasing cavity modes are typically outcoupled in a preferred direction with a defined far-field radiation pattern. For example, the output of a linear Fabry-Perot cavity is radiated from both ends of the cavity in two opposite directions, and spherical or discoidal cavities support whispering gallery modes (WGMs) that emit predominantly radially in the plane of cavity resonance. While the directionality of emission may be utilized for some applications such as motion sensing, it is generally a nuisance in other applications including cellular labeling and tracking. The orientation of LPs in a cell is arbitrary and tends to vary rapidly over time as the cell moves. This can cause random intensity fluctuations, making it difficult to detect and identify different LPs over time. It is noted that fluorescence from a single molecule is directional with a typical dipole radiation pattern. When many molecules are present with random orientations, their individual directional emission is averaged out, and the total output from the ensemble can be omnidirectional and uniform in space. The gain medium in an LP contains many emitters, but their stimulated emission is coherent with each other within a lasing cavity mode, producing a direction-dependent radiation pattern.

For LPs as freely rotating particles in aqueous solution, it is ideal to have uniform radiation patterns. For on-chip micro-lasers, it is generally preferred to direct output emission in a specific direction. For this purpose, various cavity designs and output coupling strategies have been demonstrated to direct output beams to in-plane or out-of-plane directions. These include using diffraction gratings, scatterers, mirrors, and non-planar cavities. However, omnidirectional laser emission into 4π steradians has neither been attempted nor demonstrated. Liquid-crystal microspheres have the potential of omnidirectional lasing but the large resonator size (a few tens of micrometers) required to form a radial grating makes it unsuitable for cellular applications.

Disclosed herein are embodiments of microdisk LPs with substantially omnidirectional output emission profiles. In some embodiments, light scattering elements are incorporated into microdisk lasers so as to increase the omnidirectionality by directing the emission intensity of whispering gallery modes in the direction along the disk plane to the plane normal. In other embodiments, a surface roughness is applied to microdisks. In still other embodiments, distinct scatterers are incorporated by being inscribed or attached on the periphery or surfaces of microdisks. Experimental prototypes are demonstrated, allowing the output intensity measured via an optical lens is uniform in all solid angles within a factor of 10. This represents significant improvement over conventional microdisk LPs. The benefit of this technology for cell tracking based on LPs is demonstrated.

One embodiment provides a laser microparticle for generating laser light with high omnidirectionality, including: an optical cavity including an active gain material capable of supporting one or more lasing cavity modes; and an optical scattering element which is incorporated into the optical cavity and configured to change a radiation pattern of the one or more lasing cavity modes to increase an omnidirectionality of the radiation pattern.

Another embodiment provides a microparticle for generating laser light including: an optical cavity comprising including a microdisk including an active gain material capable of supporting one or more lasing cavity modes; and an optical scattering element associated with the optical cavity and configured to change a radiation pattern of the one or more lasing cavity modes to increase omnidirectionality of light introduced into the optical scattering element.

Yet another embodiment provides a laser generating microparticle including: an optical cavity; an active gain material arranged in the optical cavity and configured to operate according to one or more lasing cavity modes; and an optical scattering element associated with the optical cavity and configured to change a radiation pattern of the one or more lasing cavity modes to direct light in a plurality of different directions when the light is introduced into the optical scattering element.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIG. 1 illustrates a conventional microdisk with directional output emission pattern, i.e. low omnidirectionality.

FIG. 2 shows the far-field radiation pattern and light-in-light-out curves of conventional microdisk laser particles with a strong difference in measured intensity on the orientation angle of particles.

FIG. 3 panels (A), (B), (C), and (D) depict several strategies to induce vertical (on-axis or out-of-plane) scattering by incorporating various scattering elements onto microdisks.

FIG. 4 shows a scanning electron microscopy (SEM) image of InGaAsP microdisks with different surface roughness levels, with the three bottom disks 410 having greater surface roughness than the upper five disks 400.

FIG. 5 depicts numerical simulation results for microdisks with scattering bumps and notches.

FIG. 6 shows experimental data obtained from different embodiments of scattering elements: rough-surface microdisks (610), rough-surface microdisks with a bump (620), and rough-surface microdisks with a notch (630), in comparison to conventional (smooth) microdisks (600).

FIG. 7 (left) shows electron microscopy images of microdisk 700 coated with silica and TiO₂ nanoparticles 710 which have a diameter of 200 nm, where the left panel is an SEM image and the right panel is a TEM image.

FIG. 8 panels (A), (B), (C), (D), and (E) show numerical simulation results for microdisks with scattering silicon nanoparticles.

FIG. 9 shows experimental demonstration of microdisk coated with silicon nanoparticles.

FIG. 10 demonstrates the reduced intensity variation or improved omnidirectionality of nanoparticle-coated microdisk particles in the cytoplasm, comparing a control LP (1000, right) to a scattering-coated LP (1050, right) in various orientations.

FIG. 11 shows a schematic of omnidirectional microdisks including additional layers with slightly different diameters.

FIG. 12 shows orientation-dependent laser emission of microdisk LPs. Panel a, Cells tagged with LPs. Two representative disk orientations are labelled. Panel b, The far-field radiation pattern |E_{far}(θ,φ)|² of the 10th order TE WGM mode of a conventional microdisk laser. Panel c, A schematic of the pumping and collection geometry. Panel d, Simulated P_{signal}(α) of a CLP. Panel e, P_{signal} versus pump energy Pₚᵤₘₚ for three CLPs suspended in hydrogel with different orientations. Insets: Corresponding optical images (i, ii, iii). Panel f, Illustration of various strategies for achieving omnidirectional emission: A deformation (notch) on the boundary of the microdisk, surface roughness, or high-index nanoparticles attached to the microdisk can redirect a portion of the lasing emission into the normal direction by elastic scattering. Panel g, Simulated Pₜₒₜ(α) of an OLP with a single 200-nm-size notch scatterer.

FIG. 13 shows orientation dependence of pump efficiency. Panel a, The spatial distribution of absorbed pump energy at different tilt angles, and the intensity profile of the cavity mode (m=10). The pump beam has a Gaussian profile with a size of 1.5 μm. Panel b, Pump efficiency versus the tile angle for pump beam diameters of 1.25, 1.5, 1.75, and 2 μm.

FIG. 14 shows laser emission from semiconductor microdisks with surface roughness and boundary defects. Panel a, SEM of a CLP with smooth sidewalls. Panels b-c, Slope efficiency (b) and threshold (c) versus orientation angle α of an ensemble of CLPs. The scattering fitting coefficient s=0.007. Black dashed curve: the theoretical prediction of a perfect microdisk. Panel d, SEM of a CLP with rough sidewalls. Panels e-f, Slope efficiency (e) and threshold (f) versus a of CLP ensembles with rough sidewalls. The scattering fitting coefficient s=0.07. Panel g, SEM of a notched LP with rough sidewalls. Panels h-i, Slope efficiency (h) and threshold (i) versus a of the notched LP ensembles with rough sidewalls. The lasing wavelengths in panels (c), (f), and (i) were 1370±10 nm, 1405±10 nm, and 1410±10 nm, respectively. The scattering fitting coefficient s=0.32. Green curves in panels b, e & h: best-fit based on Eq. (4) in the log scale.

FIG. 15 shows lasing emission of scLPs. Panel a, SEM of an array of scLPs on pillars. Panel b, SEM of a scLP after detachment. Panel c, Typical emission spectrum of a scLP fitted with a Lorentzian lineshape, showing a full width at half maximum of 0.25 nm. Panel d, Typical output curves versus pump energy for flat cLPs (gray curves) and scLPs (black curves). Panels e-f, Slope efficiency versus orientation angle α of cLP and scLP ensembles. Theoretical fits (green curves) yielded scattering coefficients of s=0.02 and s=0.2 respectively. Panels g-h, Lasing threshold of cLP ensembles and scLP ensembles as a function of disk angle α in a hydrogel.

FIG. 16 shows lasing emission of OLP in live cells. Panels a-b, A CLP (α) and OLP (b) inside live Hela cells. c, Output spectra versus orientation of a CLP in a live Hela cell. The spectra were acquired at the same time as the optical images in the insets (i-iii). Panel d, Output spectra versus orientation of an OLP in a live Hela cell. The spectra were acquired at the same time as the optical images in insets (i-iii).

FIG. 17 shows OLPs for continuous single-cell tracking. Panels a-b, Lasing-intensity (points) and orientation-angle (dashed) traces as a function of time for three tracked CLPs (α) and OLPs (b) internalized by cells. For low orientation-angles, the signal received from CLPs falls below the detection threshold, and the tracking is lost. Panels c-d, The lasing intensity versus disk angle α.

FIG. 18 shows radiation patterns of whispering gallery modes of a microdisk in water. Panels a-d, Electric-field distributions |E| and far-field radiation patterns |E_{far}| of the TE (panels a, b) and TM (panels c, d) modes. Insets of panels a and c: Cross-sections of the electric-field distributions of the TE and TM modes. The radiation-limited Q factors of the TE and TM modes are 11,500 and 113, respectively. Panel e, The far-field intensity distribution of the TE mode as a function of the polar angle, calculated by 3D FEM simulation (black dashed curve) and by scalar diffraction theory (red solid curve). The divergence angle (full width at half maximum, FWHM) is about 32°. f-g, The power P_{signal} collected by an objective lens with a finite numerical aperture (NA=0.6) for different orientations of the disk showing a pronounced dependence on the tilt angle α (f) but not on the azimuth angle φ (g). (black: 3D FEM simulation; red: scalar diffraction theory).

FIG. 19 shows lasing threshold and linewidth of conventional LPs. Panel a, P_{signal} versus pump energy Pₚᵤₘₚ on a logarithmic scale of CLPs suspended in hydrogel with different orientations in FIG. 12e. The lasing wavelength of these samples ranges in 1230-1310 nm. Panel b, Typical single-mode emission spectrum of a microdisk (made from a different wafer with a gain bandwidth at 1500-1600 nm). Red curve: fit with a Lorentzian line-shape with a FWHM of 0.23 nm. Panel c, Normalized lasing emission spectra of a batch of conventional LPs made from another wafer with a different gain bandwidth.

FIG. 20 shows numerical simulation of OLPs with a boundary defect. Panel a, Electric-field distribution of the TE mode of a conventional LP. Panel b, Pₜₒₜ(0°) and Q factor of an OLP with a boundary defect as functions of the defect size. Positive diameters correspond to a protrusion (bump) and negative to an indentation (notch). Panel c, Electric-field distributions of a TE mode of a microdisk versus defect size. Panels d-e, Simulated Pₜₒₜ(α) for a microdisk with a 200-nm-diameter hemicylindrical boundary notch (d, TE mode; e, TM mode). Panel f, Mode pattern (inset) and simulated Pₜₒₜ(α) of an OLP with 15 bumps each with a diameter of 140 nm placed randomly on the boundary of disk. The corresponding radiation and scattering limited Q factor is 1,200.

FIG. 21 shows lasing emission of LPs with boundary defects. Panel a, SEM of arrays of bump and notch LPs after the reactive ion etching step, showing the photoresist (PR), active layer (AL) and substrate layer (SL). Panel b, SEM of bumped and notched disks after detachment. Panel c, Slope efficiency versus tilt angle α of bumped and notched disks with smooth (circles) and rough (diamonds) sidewalls. Panel d, SEM and lasing-intensity maps of circular, bumped, and notched disks with rough sidewalls on support pillars at the same pump energy (at 100 μs exposure time per pixel). The NA of the objective lens is 0.45 in c and 0.85 in d.

FIG. 22 shows numerical simulation and optical characterization of scLPs. Panel a, Pₜₒₜ(0°) and Q factor for a microdisk with a single silicon nanoparticle (SiNP) resting on its surface as functions of the particle size. Here, the diameter of disk is 2.5 μm and the distance between the SiNP and the disk is 15 nm. Inset: the simulation model. Panel b, Simulated Pₜₒₜ(α) of a scLP with 100 small SiNPs (diameters: 50-100 nm) embedded in a silica capping layer (thickness: 250 nm), with a SiNP-disk gap distance of 15 nm. The radiation-scattering limited Q factor of the resonance mode is 4,500. Panel c, Simulated Pₜₒₜ(α) of a scLP with 50 large SiNPs (diameters: 100-200 nm) embedded in a silica capping layer (thickness: 250 nm), with a different SiNP-disk gap distance: g=15 nm (red), 65 nm (blue), and 105 nm (yellow). The radiation-scattering limited Q factors of corresponding resonance mode are 2,600 (g=15 nm), 3,700 (g=65 nm), 4,300 (g=105 nm) respectively. Panel d, Fabrication process of scLPs. The separation between the disks and the nanoparticle layer is controlled by the thickness of the initial SiO₂ layer deposited by PECVD. Panel e, Density control of SiNPs spin-coated on an InGaAsP wafer. Panel f, SEM of a control LP (left) and a scLP (right) on pillars. Panel g, Optical images and corresponding lasing-intensity maps of a control LP (i, ii) and a scLP (iii, iv). The lasing-intensity maps of both control LP and scLP were obtained at the same pump energy. Panel h, The output emission versus pump energy on a logarithmic scale for three representative flat (α=0)) cLPs (top) and scLPs (bottom) in FIG. 15d.

FIG. 23 shows lasing emission of scLPs obtained by chemical functionalization. Panel a, Simulated model of a scLP in which 47 spherical nanoparticles (diameter: 200 nm) are randomly distributed around the disk. The gap distance between the disk and nanoparticles is 50 nm with a refractive index of 1.40, and the refractive index of environment is 1.334. Panel b, Simulated Pₜₒₜ(α) when the refractive index of the nanoparticles is 1.334, 1.5, 1.8 and 2.0. Panel c, Pₜₒₜ(0°) and radiation-scattering limited Q factor versus the refractive index of the nanoparticles. Panel d, Chemical functionalization of scLPs. Panel e, SEM of a conventional LP. Panel f, SEM and TEM (inset) of a scLP covered with 200-nm-diameter TiO₂ nanoparticles. Panels g-h, Slope efficiency versus orientation angle α of CLPs and scLPs suspended in hydrogel.

FIG. 24 shows simulated Pₜₒₜ(α) of omnidirectional LPs considering the protective silica coating and different mode number. Panel a, Semiconductor microdisk with a 200-nm-diameter semicylindrical notch on the boundary. Panel b, Semiconductor microdisk coated with a scattering layer (scLP) in which silicon nanoparticles (100-200 nm diameter) are embedded in a 250-nm-thickness capping silica layer. The thickness of the protective silica coating is 250 nm. The refractive indexes of the semiconductor microdisk, silicon nanoparticles, silica coating and the surrounding environment are 3.45, 3.48, 1.46 and 1.33 respectively. The radiation-scattering limited Q factors: (a) 1,000 for notched LP without silica coating and 1,400 for LP with silica coating; (b) 2,400 for scLP without silica coating and 1,900 for scLP with silica coating. Panels c-d, Simulated Pₜₒₜ(α) of notched LP (c) and scLP (d) for cavity modes with different azimuth mode number.

FIG. 25 shows laser mode position versus tilt angle of microdisk LPs. Panel a, A schematic of the experimental setup. Panels b-c, The lasing spectra versus the title angle of two representative microdisk LPs on supporting pillars.

FIG. 26 shows a far-field radiation pattern |E_{far}(θ)|² (panel a) and the collected output emission P_{signal}(α) (panel b). Red solid curves: the scalar diffraction theory; Gray dashed curves: 3D FEM simulation. Black solid curve: the fitting curves of |E_{far}(0)|²=sin¹⁸(θ) (a) and P_{signal}(α)=sin¹⁰(α) (b).

FIG. 27 shows the ratio R of the minimum and maximum intensities P_{signal} as a function of NA/n. Red solid curve: n=1; Gray dashed curve: n=1.33; Black solid curve: Fitting curve: R=110 (NA/n−1) dB.

FIG. 28 shows the effect of tissue scattering on angle dependent collection. Sample photon paths from a Monte Carlo simulation for (panel a) a flat disk situated at depth z=0.3 mm, and (panel b) a vertical disk situated at a depth z=0.3 mm. Panel c, The normalized power collected at different angles for depths 0.1, 0.3 and 0.5 mm with fitting curves.

### DETAILED DESCRIPTION

An intrinsic feature of LPs is that their output emission occurs in specific directions determined by the lasing cavity mode. Microdisk LPs supporting whispering gallery modes (WGMs) emit predominantly in the plane of the cavity resonance. The directionality of laser emission, however, hinders the reliable optical reading of LPs when their orientations with respect to optical instruments change. This is a general problem in almost all applications of LPs as this new type of lasers are intended to operate with arbitrary, often freely-moving, orientations. Cell tracking represents this situation. The orientations of LPs in a cell is arbitrary and tends to vary over time as the cell moves. During tracking this can cause random intensity fluctuations and frequent loss of the measured laser signal, making it difficult to detect and identify the LPs reliably over time. We have encountered this problem in our previous study of spheroids in vitro. The light scattering in biological tissues does not mitigate this problem because the high-resolution spectral readout of LP emission requires confocal detection of essentially non-scattered, or minimally-scattered, light. Furthermore, the detection of LPs in instruments with dynamic environments such as microfluidic channels would severely suffer from the angular dependence of emission. Therefore, addressing the directionality of laser emission would have a high impact on the broad utilities of LPs.

Previous work on microlasers for on-chip applications mainly focus on directing the in-plane emission of WGM microlasers to a specific direction by introducing boundary deformations, diffraction gratings, or scatterers. Nevertheless, omnidirectional laser emission into 4π steradians has neither been attempted nor demonstrated. Liquid-crystal microspheres have the potential of omnidirectional lasing but the large resonator size (tens-of-micrometers) required to form a radial grating is unsuitable for intracellular applications.

Here, we demonstrate omnidirectional emission from microdisk LPs by incorporating light scattering into the cavity. Among the various approaches we have explored, two designs of omnidirectional LPs (OLPs) are described here: one introduces boundary defects on the cavity design, and the other uses nanoparticles attached around the resonators. The laser power collected from our OLPs varies by less than 10 dB as a function of their orientation, while this same variation exceeds 24 dB for conventional microdisk LPs (CLPs). We find that despite the strong scattering and large aspect ratio of both OLP designs, single-mode lasing is realized with low lasing threshold and narrow linewidth nearly independently of their orientation. We have applied one of the designs to produce OLPs in large quantities for a proof-of-concept demonstration of reliable single-cell tagging and blinking-free cell tracking. Traces of OLPs based on their output spectra in live cells show a high signal-to-noise ratio (SNR) in every single frame for two hours in practical settings, while with CLPs the signal is below the noise level in many frames.

Accordingly, various embodiments provide a microparticle for generating laser light. The microparticle may include an optical cavity which may include a microdisk having an active gain material capable of supporting one or more lasing cavity modes, where the active gain material may include a semiconductor.

The microparticle may also include an optical scattering element associated with the optical cavity and configured to change a radiation pattern of the one or more lasing cavity modes to increase omnidirectionality of light introduced into the optical scattering element. In certain embodiments the microdisk may have a diameter of less than 10 μm. In some embodiments, the omnidirectionality of the radiation pattern is indicated by an omnidirectionality index, which in particular embodiments may be greater than 0.10 or greater than 0.25.

In various embodiments, the optical scattering element includes a modification of a surface of the microdisk. In some embodiments, the modification of the surface may include a modification of an edge of the microdisk. In particular embodiments, the modification of the edge of the microdisk may include a nanometer-scale roughness in a surface of the optical cavity. In other embodiments, the modification of the edge of the microdisk may include at least one of a bump or a notch on the edge of the microdisk, where the bump or the notch may have a radius in a range of 50 nm to 400 nm, and in particular may have a radius of 100 nm.

In certain embodiments, the modification of the surface of the microdisk may include a nanoparticle coupled to the microdisk, where the nanoparticle may include a high refractive-index material which may include at least one of silicon or a III-V semiconductor. In various embodiments, the nanoparticle may have a diameter in a range of 100-200 nm. In some embodiments, the microdisk may include between 10 and 50 nanoparticles.

In one embodiment, the optical scattering element may include a feature layered axially with respect to the microdisk, wherein the feature has a different radius than the microdisk.

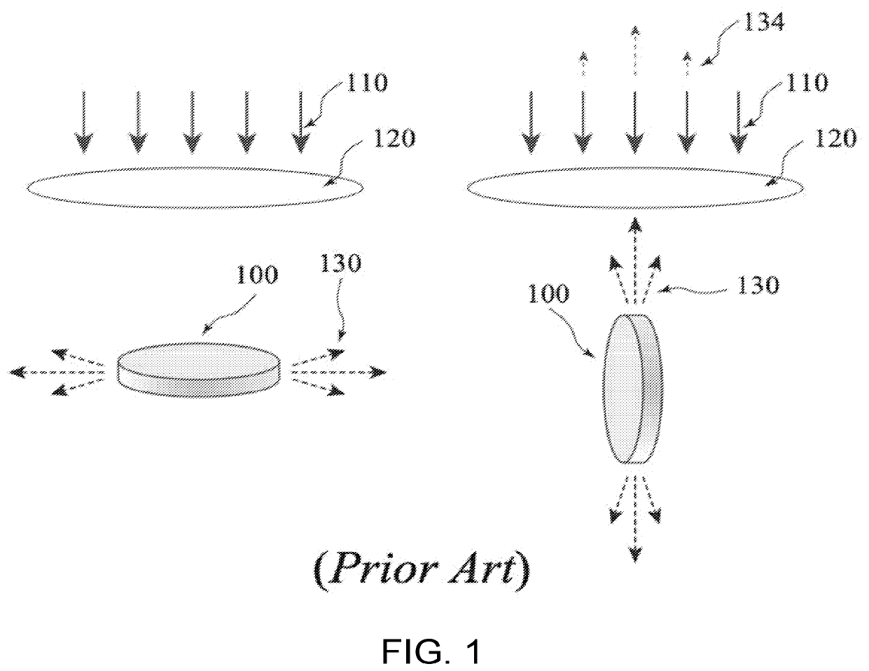

FIG. 1 shows a conventional microdisk laser 100. Typically, it is fabricated from a semiconductor wafer using lithography and appropriate dry and wet etching. Microdisks support whispering gallery modes (WGM's) circulating the disk resonator as guided between the two side surfaces and confined by total internal reflection from the side surface. When pump energy 110 with sufficient intensity and wavelength is provided, typically via an optical lens 120, one or more of the WGM's can lase. The radiation intensity of the lasing cavity mode(s) has a specific spatial profile determined by the particular mode. For conventional microdisk lasers, the radiation intensity 130 is dominantly concentrated within a small angle with respect to the plane of the disk. The far-field output intensity along the axis normal to the disk plane is close to zero. This angle dependence makes the measurement of laser emission from the microdisk vary depending on the orientation of the LP. For example, when the disk plane is oriented parallel to the direction of light collection (FIG. 1 right panel), the measured intensity 134 is much stronger than when the collection direction is orthogonal to the disk plane (left panel), as illustrated in FIG. 1.

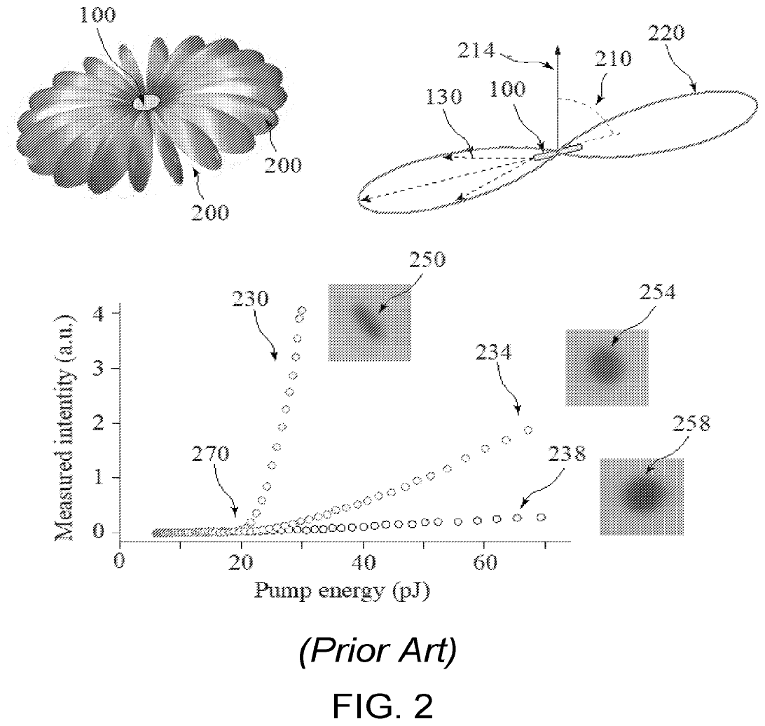

FIG. 2 further illustrates the direction-dependence of conventional microdisk lasers. As light circulates around the periphery of the resonator, a small portion leaks out of the side of the disk with each reflection, resulting in a characteristic pattern. Consider a single-mode WGM microdisk made of InₓGa₁₋ₓAs_{1-y}P_{y} semiconductor (e.g. x=0.5-0.8, y=0-0.6) with a diameter of 2 μm and a thickness of 200 nm. The lasing cavity mode, with the highest Q-factor, is the 10-th order transverse-electric (TE) WGM. Let |E|² (θ, ϕ) describe the normalized far-field intensity profile of the lasing mode 200, where θ is the polar angle with respect to the disk normal, and ϕ is azimuthal angle. In this example, we can approximate |E|²(θ, ϕ)∝exp(−θ²/2θ₀²)·cos²(lϕ), where l (=10) is the mode order, and θ₀ (≈9 deg) is the spread angle depending on the radius and height of the microdisk. Experimentally, the output emission is collected by a lens 134 with finite numerical aperture (NA). The measured intensity pattern is therefore given by l₀ (α)∝∫∫^{Ω}|E|²(ϕ, θ) sin θdθdϕ, where the integration runs over the emission-collection solid angle 2 centered at a, where a represents the angle between the viewing direction and the microdisk plane. The exact solution of the integration can be computed. For NA≈0.45, empirically I₀(α)≈|cos(α)|^{m}, where m≈4, describes the normalized output intensity pattern of such a microdisk laser particle with reasonably good accuracy.

When the microdisk is oriented with an angle 210 with respect to the light collection direction 214, the measured output intensity 220 has a strong angle dependence or directionality. For example, the output intensity curves 230, 234, 238 of three different microdisks 250, 254, 258, measured as a function of pump pulse energy are shown in FIG. 2. All three LPs have a similar lasing threshold 270 at a pump energy of about 20 pJ. However, the increase of the output intensity above threshold, or the slope efficiency, is drastically different among the LPs. The microdisk 250 oriented parallel to the collection axis has the highest slope efficiency 230. The microdisk 254 tilt by about 45° has an intermediate slope efficiency 234. And, the microdisk 258 oriented orthogonal to the light collection axis has the smallest slope efficiency 238.

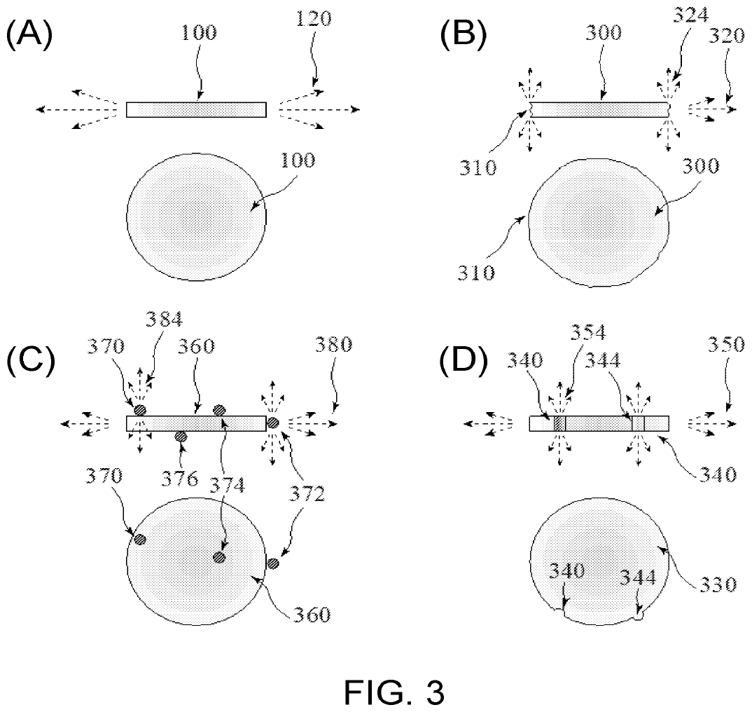

FIGS. 3(A)-3(D) illustrate three strategies to reduce the direction dependence to make the radiation emission more toward all directions, i.e. to improve omnidirectionality. As a metric, we may define an ‘omnidirectionality index’, which is given by the ratio of the minimum value of I(α) to the maximum value of I(α) for the given NA of an optical system. For a perfectly round microdisk 100 (FIG. 3(A)), the omnidirectionality index is extremely small, <0.001. In practice, the surface of microdisks 300 is not perfectly round and smooth, and this roughness 310 scatters the lasing mode toward vertical directions. In this case, the total output intensity can be expressed as a sum of un-scattered intensity profile I_{un-sc}(α), 320, and scattered intensity profile I_{sc}(α), 324 (FIG. 3(B)):

$${I}_{t o t} ( α ) = {I}_{un - sc} ( α ) + {I}_{s c} ( α ) \qquad ( 1 )$$

We introduce a scattering coefficient s, where I_{un-sc}(α)=(1−s)I₀(α). The specific form of I_{sc}(α) depends on the specific shape, size, and distribution of the scatterers, but when the characteristic size of the roughness in the surface is much less than the optical wavelength, e.g. <20 nm, I_{sc}(α) can be expressed as s*I_{Rayleigh}(α), where I_{Rayleigh}(α) describes a dipolar radiation pattern with lobes toward the vertical (disk-plane normal) directions.

For s<<1, the omnidirectional index is approximately equal to s/(1−s). The index is maximized 1 when s=0.5. For practical applications, an omnidirectionality index greater than 0.1 is desirable. This can be achieved with a scattering coefficient s greater than 0.1. This condition may be achieved by deliberately introducing sufficiently large roughness on the side surface of microdisk lasers.

Another approach to increase the scattering coefficient relative to a pristine microdisk 100 is to introduce one or more defined defects, such as bump 344 or notch 340 elements (FIG. 3(D)). A scatter with a size comparable to a quarter to a full optical wavelength in the cavity (e.g. 100-400 nm for a vacuum wavelength of 1200 nm in a refractive index of 3, or 50-200 nm for a wavelength of 600 nm) causes Mie-type scattering with an intensity profile I_{Mie}(α). Then Eq. (1) may be written as:

$${I}_{t o t} ( α ) = ( 1 - s ) {I}_{0} ( α ) + s * {I}_{M i e} ( α ) \qquad ( 2 )$$

Where the first term describes un-scattered light 350 and the second term describes vertically scattered light 354.

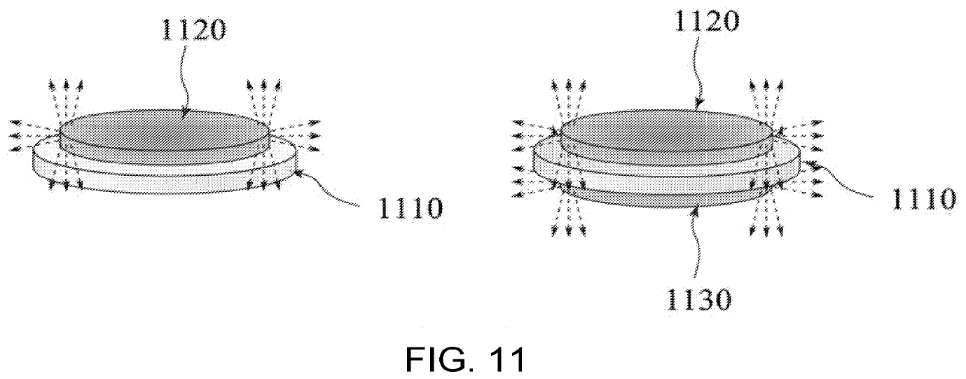

Another effective approach is to attach scattering elements to microdisks 360 (FIG. 3(C)). For example, submicron particles 370, 372, 374, 376, (nanoparticles) can be attached physically or chemically on or near the surface of microdisks. Depending on the size of the particles, Rayleigh or Mie scattering can be produced to generate out-of-plane vertical scattering 384. In various embodiments, the different scattering methods described in FIG. 3 may be combined to together to optimize output patterns and increase the omnidirectional index. In other embodiments, one or more of these methods may be combined with other methods of scattering such as that shown in FIG. 11 to further optimize output patterns and increase the omnidirectional index.

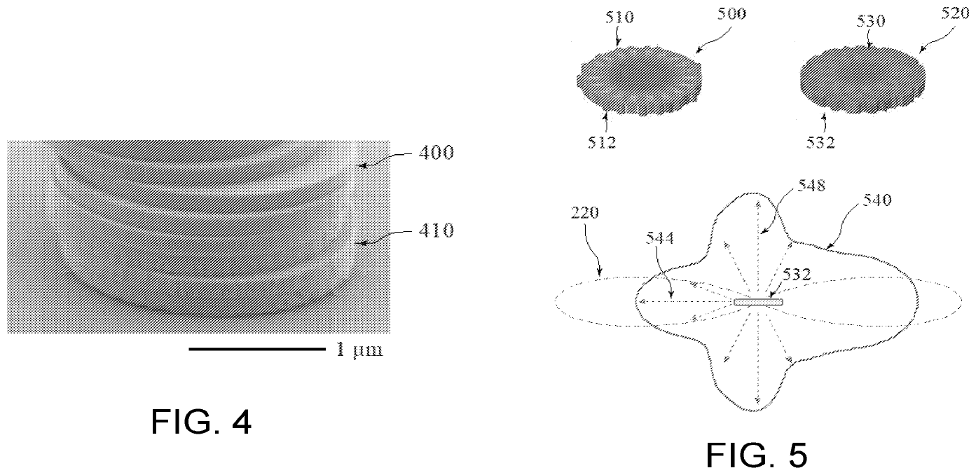

FIG. 4 shows a scanning electron microscopy (SEM) image of a stack of semiconductor microdisks with different roughness. The bottom three disks 410 have substantially more rough side edges compared to the five microdisks above 400. The difference in roughness was introduced by different reactive ion etching (RIE) conditions. An excessive RIE time can damage a photoresist mask, such as SU8, and result in rough surface. Using ions that are more likely to scatter sideways to attach the side wall of microdisks is another method to increase surface roughness.

FIG. 5 (upper panels) depicts numerical simulation results for a microdisk 500 with a number of bumps, 510, 512 (upper left panel), and a microdisk with several notches 530, 532 (upper right panel). The output emission pattern 540 from such an LP 532 consists of un-scattered light 544 and vertically scattered light 548 with about equal magnitudes (lower panel). The scattering coefficient is close to 0.5 and the omnidirectionality index is about 0.5.

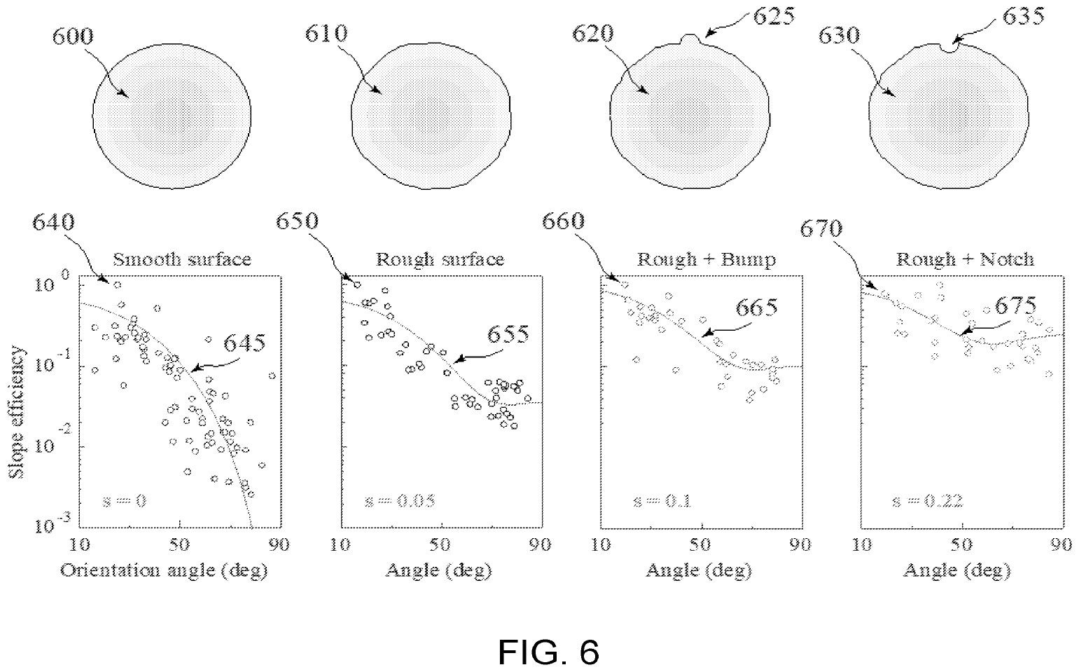

FIG. 6 shows experimental demonstrations of the scattering strategies described in FIG. 3. Four different types of InGaAsP microdisks are compared: (i) InGaAsP microdisk 600 with relatively smooth surface, (ii) microdisk 610 etched to have increased roughness, (iii) microdisk 620 fabricated to have increased roughness and a bump 625 with a radius of 100 nm, and (iv) microdisk 630 with rough surface and a notch 635 with a 100-nm radius, although in various embodiments the radius of the bump or notch may range from 50 nm to 400 nm. Light-in-light-out curves were measured from many LPs of each type embedded in hydrogels with random orientations. The slope efficiency of each LP was computed from the data. The result 640 obtained from pristine smooth microdisks 600 showed significant angle dependence, which is fit quite well with I₀(α)≈cos⁴(α), 645, and s=0. The data 650 from rough-surface microdisks 610 were best fit with a curve 655 with s=0.05. Data 660, 665 for rough-surface microdisks with bumps 620 shows an increase in the scattering coefficient to s=0.1. Data 670, 675 for rough-surface microdisks 630 with notches shows the vertical scattering increases to s=0.22. The laser threshold pump energy was similar for all four types and was in a narrow range around 5 pJ. Therefore, the slope efficiency represents the magnitude of output intensity at a given pump level above threshold. From the laser-to-laser variation of the slope efficiency, it is estimated that the omnidirectionality index is improved from <0.01 in pristine microdisk to >˜0.1 by having the Rayleigh and Mie scatterers on the side wall of microdisks, 620, 630.

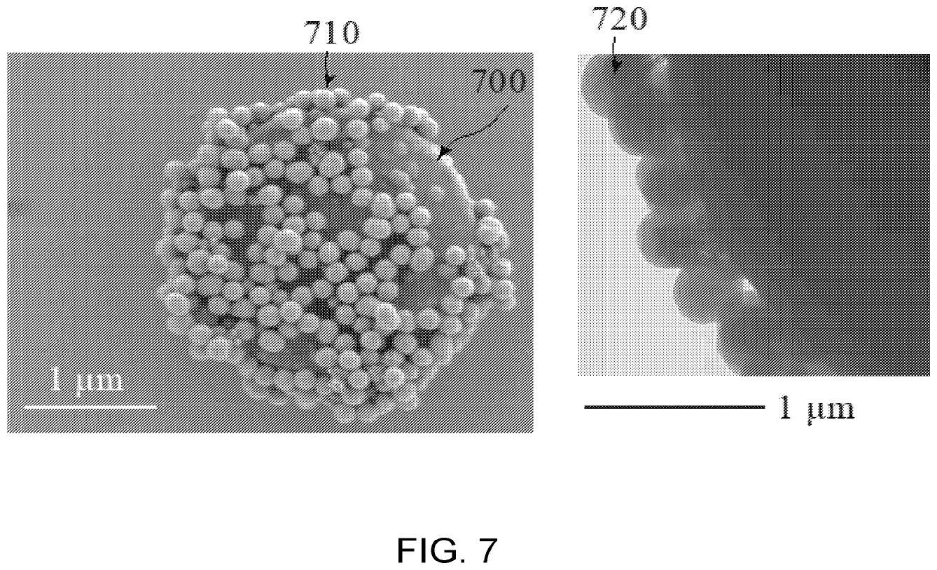

FIG. 7 (left) shows another experimental embodiment based on scattering nanoparticles illustrated in panel (C) of FIG. 3. First, pristine semiconductor microdisks were coated with silica using a modified Stober process previously described. Then, the amine group was attached to the silica, and then TiO₂ nanospheres 710 functionalized with carboxyl groups were conjugated to the surface 710, as shown in the SEM image in the left panel of FIG. 7. A transmission electron microscopy (TEM) image (FIG. 7, right) shows the attached TiO₂ particles, which have a diameter of ˜200 nm. Measurement on these samples showed that the improvement of omnidirectionality index is moderate, presumably because of the relatively moderate refractive index (n≈2) of TiO₂ nanospheres/particles. Different scattering elements made of higher index material, such as silicon and III-V semiconductor, may be used and can be attached using similar chemical protocols and would be expected to provide an increase in omnidirectionality index compared to the TiO₂ particles.

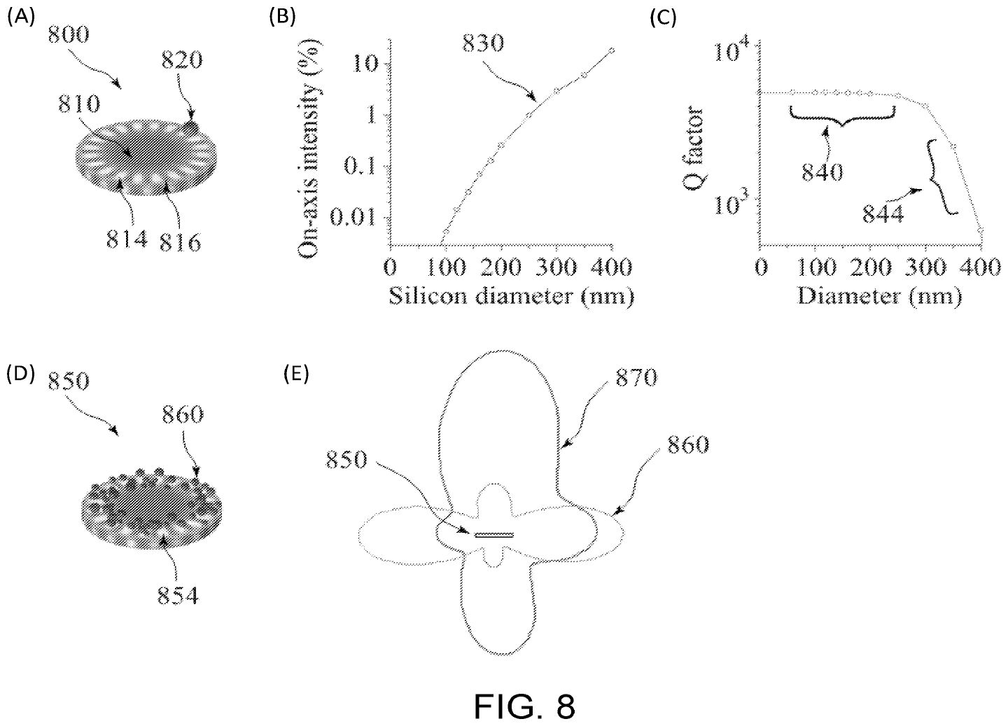

FIG. 8 shows numerical simulation results for silicon nanoparticles with different size and numbers. A single silicon particle 820 (FIG. 8(A)) on the edge of a microdisk 810 affects the resonant cavity mode (peak 814 and valley 816 of the standing wave pattern) and scatters its emission to the on-axis (vertical, out of plane) directions. The finite-difference time-domain simulation result 830 (FIG. 8(B)) indicates that the magnitude of on-axis intensity increases nearly exponentially with increasing particle diameter. A single silicon particle with a diameter of 100 nm can generate s=10⁻⁴, and the scattering coefficient increases to s=10⁻³ with a diameter of 200 nm without degrading the quality (Q) factor 840 of the microdisk cavity (FIG. 8(C)). Particles larger than 300 nm can produce larger scattering but lower Q-factor. Therefore, a desirable design is to incorporate multiple silicon nanoparticles each with a diameter smaller than 200 nm. An exemplary microdisk laser 850 includes a microdisk 854 and 50 silicon particles 860 with diameters in a range of 100 to 200 nm (FIG. 8(D)). The silicon nanoparticles are attached on one side of the microdisk 854 and embedded in a silica coating with a thickness of 300 nm. Such an LP can produce substantial vertical on-axis (out-of-plane) scattering, 860, 870 (FIG. 8(E)). The scattering coefficient 860 is s=≈0.3 when the particles have a gap distance of ˜100 nm from the surface of the microdisk. Scattering is increased 870 when the separation is reduced to 15 nm (FIG. 8(E)).

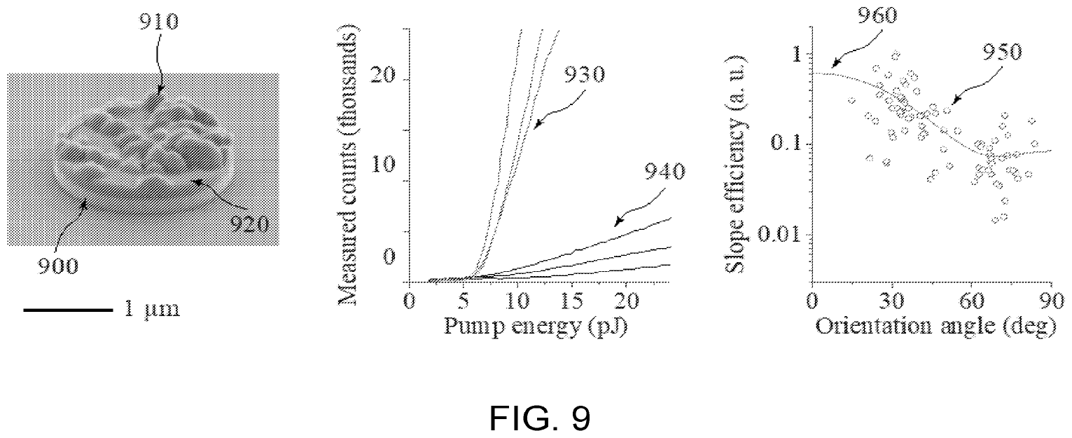

FIG. 9 (left) shows an SEM image of an experimental demonstration of the embodiment of FIG. 8(D). InGaAsP microdisks are fabricated with a modified procedure as follows. On the surface of an uncapped InGaAsP-on-InP wafer 900, a thin spacer silica layer is deposited by plasma-enhanced chemical vapor deposition (PECVD). This layer serves as a gap (˜15 nm) separating nanoparticles from semiconductor. Silicon nanoparticles 910 with diameters between approximately 30 and 50 nm are then dispersed on the sample surface by spin coating. Next, a second silica layer 920 is deposited which has a thickness of ˜250 nm, encapsulating the nanoparticles 910. Microdisks are then produced from the wafer following a standard optical lithography and reactive ion etching process flow. The average number of silicon nanoparticles per disk ranges from 5 to 50. Characterizations of these particles and control (silica coating without nanoparticles) particles embedded in a hydrogel show that the incorporation of silicon nanoparticles does not affect neither the threshold energy (˜6 pJ) nor laser output linewidth (0.25 nm) compared to the control particles. However, measured light-in-light-out curves show much improved on-axis intensity with nanoparticles 930 compared to the control 940 (FIG. 9, center). The plot of the measured slope efficiency 950, 960 as a function of disk orientation indicates a scattering coefficient of s=0.13 (FIG. 9, right). This result demonstrates an order-of-magnitude improvement of omnidirectionality with the nanoparticle coating. These experiments show that the use of silicon nanoparticles as small as 30 nm in diameter is still effective at achieving a high degree of omnidirectionality in real-world applications. Likely, the effects are stronger than those predicted by simulation since the nanoparticles occasionally deviate from sphericity and are also prone to forming aggregations on the microdisk surface leading to the formation of highly scattering clumps of silicon nanoparticles.

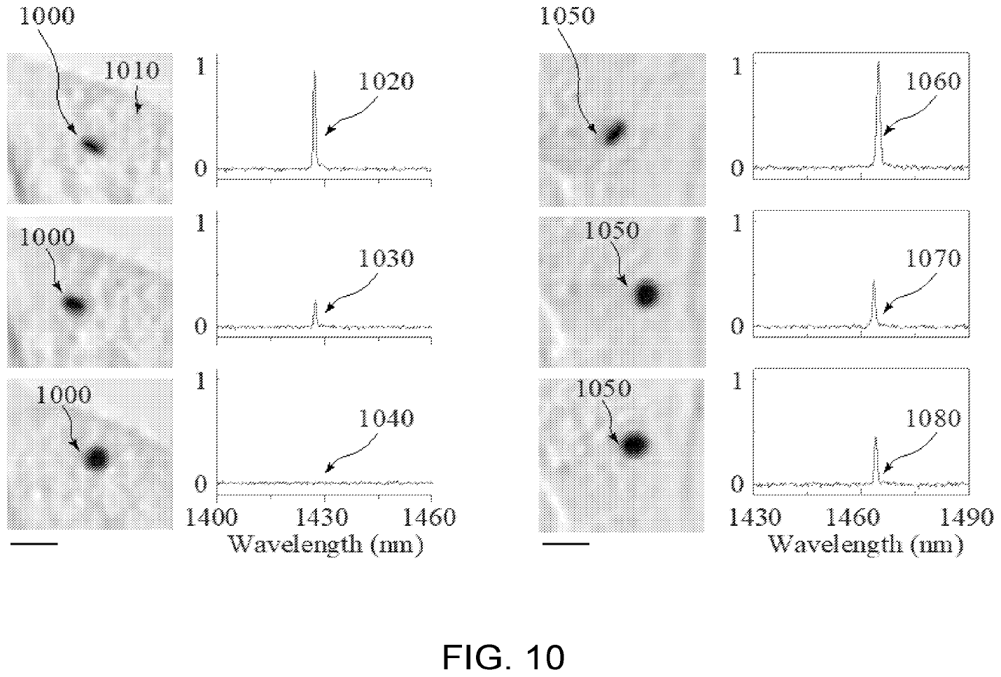

FIG. 10 illustrates the benefit of increased omnidirectionality for cell tracking applications. For this experiment, microdisks coated with silicon nanoparticles (1050) were internalized into Hela cells via macropinocytosis. For comparison, control microdisks (1000) were incubated with a separate group of Hela cells. A control LP 1000 with a low omnidirectional index of <0.01 exhibits considerable changes in the output intensity as the disk orientation in a cell 1010 is altered from parallel 1020 to orthogonal 1040 to the light collection axis. By contrast, a scattering-coated LP 1050 with a high omnidirectional index of >˜0.3 generates strong intensity at all orientations 1060, 1070, 1080, of the microdisk 1050. Advantages of this high signal includes high accuracy and sensitivity in the measurement of the lasing wavelength of the LP as well as the location of the LP. The low signal variation also relaxes the specification for the dynamic range of detectors for detecting output emission and for avoiding detector saturation.

FIG. 11 shows yet another embodiment of omnidirectional microdisks that include additional layers having different diameters. Alternative surface scattering features can also be used along with the varying-diameter layers to promote omnidirectional emission. For example, on-chip microdisks are usually attached to a wafer substrate via a columnar pedestal which is formed by undercutting a sacrificial layer beneath the microdisk active material. If this pedestal is too large, the optical mode of the microdisk cavity can interact with it, inducing scattering with a component normal to the disk plane. Therefore, omnidirectionality could be induced by leaving a thin, residual pedestal 1120 permanently attached to the disk. Such a pedestal could be present on one (FIG. 11, left) or both (FIG. 11, right) sides of the disk surface and could be made from a variety of materials including high refractive index materials such as, for example, amorphous silicon (a-Si) or InₓGa₁₋ₓAs_{1-y}P_{y}. The advantage of such an approach is that omnidirectional microdisk lasers could be directly fabricated without requiring post-chemical modification, and could be made to a high degree of repeatability and precision without the need for high resolution lithography required for patterning boundary defects (e.g. bump, notch).

For example, a-Si could be deposited by PECVD on the surface of the cavity material 1110. Following definition of disk geometry, the size of the a-Si could be finely tuned by, for example, a number of XeF₂ etching cycles, which is a known technique used in precision silicon MEMS fabrication. To prevent thinning of the a-Si, it would be possible to cap the a-Si with a silica layer, which could later be removed selectively by HF etching. Alternatively, the thin, residual pedestals could be made of a material grown lattice matched to the original substrate. For example, a composition of InₓGa₁₋ₓAs_{1-y}P_{y} with x and y close to 1 would resemble InP and so would etch faster in HCl than an InₓGa₁₋ₓAs_{1-y}P_{y} disk with x′<x, y′<y, enabling residual pedestals 1120 and 1130 of the material to remain attached to the detached microparticle.

In summary, disclosed herein are several working embodiments of microdisk lasers having improved omnidirectionality in output emission. A single microdisk has been considered in the embodiments, but the same principle based on scattering can be applied to multiple laser particles, each of which consists of multiple (typically 2 to 9) microdisks for generating multiple laser emissions. While the exemplary embodiments are demonstrated with semiconductor microdisk lasers, the same approach based on incorporating scattering elements at and near the surface of optical cavities can be extended for other types of LPs, such as microsphere lasers, organic micro-lasers, semiconductor nanowires, and submicron laser particles, where surface roughness, bumps, notches, and nanoparticles can be used to increase omnidirectionality. Overall, the scattering-based strategy to improve omnidirectionality can be applied to various laser particles with a size ranging from 0.5 μm to 10 μm. Furthermore, this approach is applicable to optical microcavity particles to alter the input and output coupling of cavity resonance modes.

### Examples

Following are non-limiting examples of procedures that may be performed using one or more of the disclosed apparatus, methods, or systems:

### In-Plane Emission of Microdisk LPs

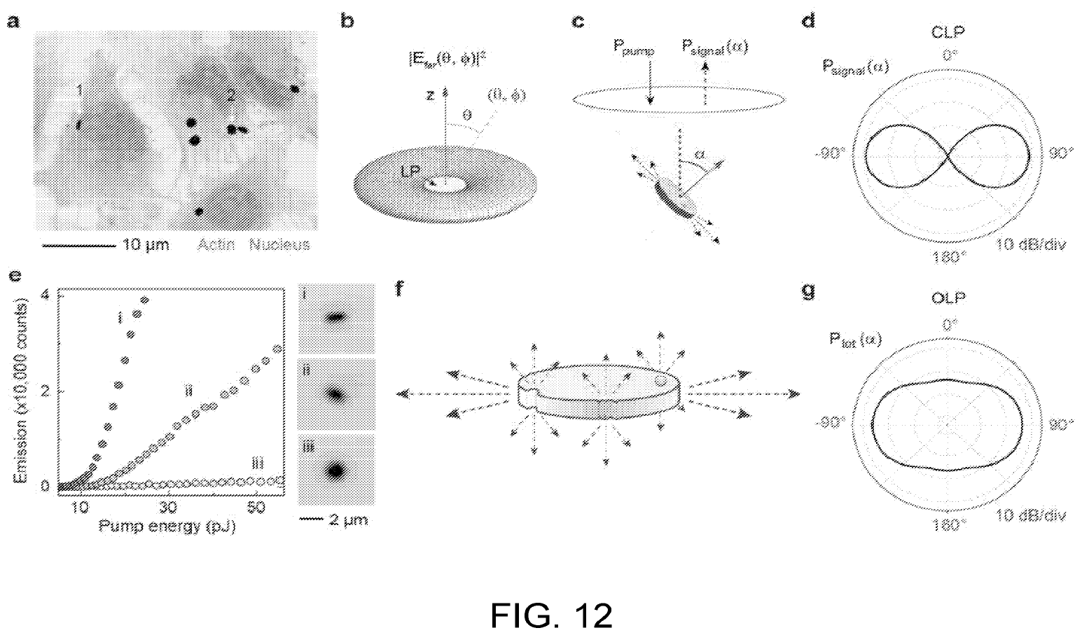

Semiconductor microdisk lasers using InGaAsP active gain material were produced using established procedures. The microdisks were released from the substrate by wet chemical etching and loaded into cells. The orientation of LPs in tagged cells is arbitrary (FIG. 12a) and tends to vary rapidly over time as the cell moves.

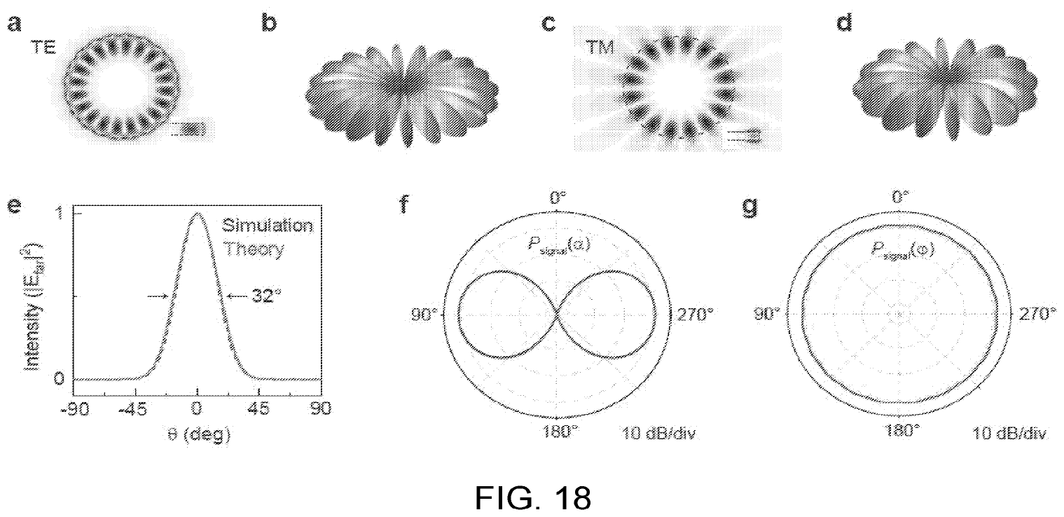

Consider a typical semiconductor microdisk laser with a diameter of 2 μm and thickness 200 nm. Finite-element-method (FEM) simulations identify the transverse-electric (TE, meaning E_{z}=0) WGM at a representative wavelength of 1270 nm (FIG. 18a) as the mode with the highest passive quality factor (radiation-limited Q_{rad}>10⁴) within the gain bandwidth of the semiconductor material. Therefore, it is the fundamental TE mode that lases. The transverse-magnetic (TM) mode has a lower quality factor and does not reach lasing threshold easily because of gain competition with the TE mode. As intracavity light circulates along the periphery of the resonator, a small portion leaks out of the side of the disk with each reflection, resulting in emission predominantly in the plane of the disk (FIG. 12b). The far-field E-field pattern of the cavity mode can be calculated (See below): E_{far}(θ,φ)≈|sin θ|⁹ e^{imp}, where m (=10) is the mode order, and (θ,φ) are defined in the spherical coordinate system fixed to the reference frame of the LP (FIG. 12b).

The output emission is collected with a finite numerical aperture (NA). For a microdisk LP tilted with respect to the viewing axis by an angle α, the power collected is given by

$${P}_{signal} ( α , NA ) ∝ {\int }_{Ω} {\vert {E}_{far} ( θ , ϕ ) \vert}^{2} sin θ d θ d ϕ , \qquad ( 3 )$$

where the integration is performed over the solid angle Q defined by a cone with half angle α sin(NA/n) centered on α (FIG. 12c), and n is the refractive index of the surrounding material (n=1.33 for an aqueous medium). When standing waves are formed by two counter propagating WGMs (FIG. 18g), the lobed azimuthal structure in the far-field intensity profile will be approximately averaged out provided the collection NA is greater than 0.5πn/m, or >0.2 for m=10.

FIG. 12d illustrates that the simulated power P_{signal} collected by an objective with an NA of 0.45 is highly dependent on the tilt angle α of the disk. The acceptance angle of light collection in the aqueous medium is sin⁻¹(NA/n)=19.8° with Ω=0.37 sr. Approximately, P_{signal}∝ sin¹⁰(α) for NA=0.45. The maximum intensity is obtained at α=90°, corresponding to a microdisk LP that is oriented along the measurement direction (e.g. disk 1 in FIG. 12a), while the minimum intensity is obtained at α=0° from a flat disk (e.g. disk 2 in FIG. 12a). To quantify this angle dependence, we calculate the ratio R of the minimum and maximum powers, or dynamic range of intensity, from the result of Eq. (3). The ratio measured in the FEM simulation is −37 dB for NA=0.45.

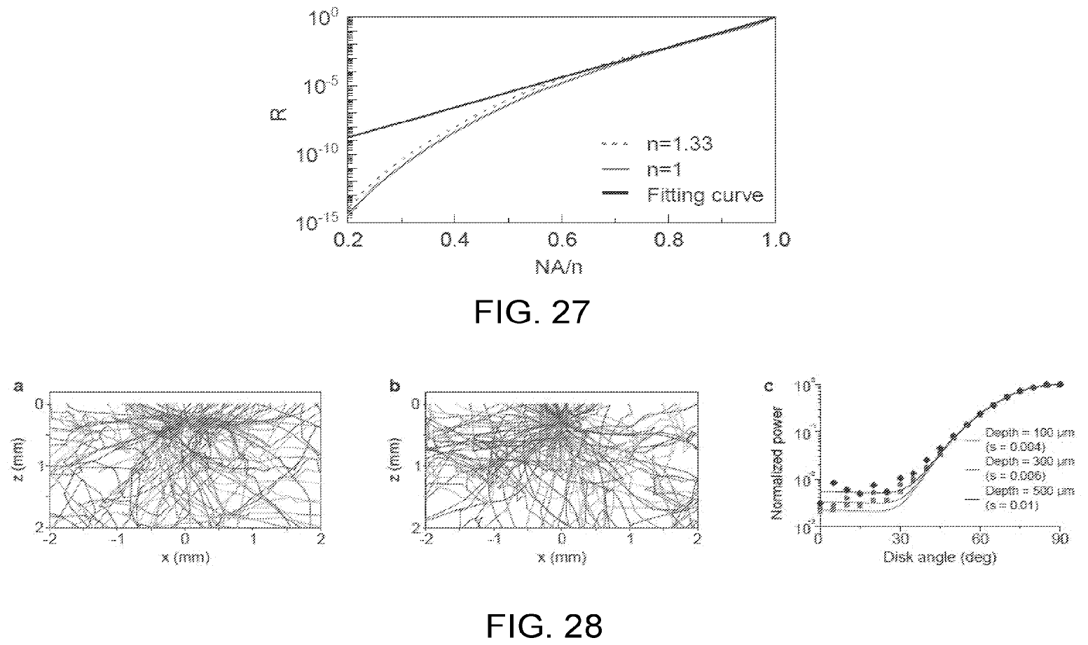

The criterion for omnidirectionality may be defined as R >0.01 or −20 dB, since this could result in an adequate SNR when a spectrometer with a typical dynamic range of 30 dB is used. We consider R>0.1 highly omnidirectional. It should be noted that R is a function of the NA of light collection (See below, FIG. 27). R>0.01 and R>0.1 could be achieved in principle using NA>1.1 and NA>1.23, respectively. However, such high NA may not be applicable under certain experimental conditions and is not possible without immersion lenses. In the following, the angle-dependence emission is characterized for NA=0.45, which gives a diffraction-limited volume encompassing an entire microdisk.

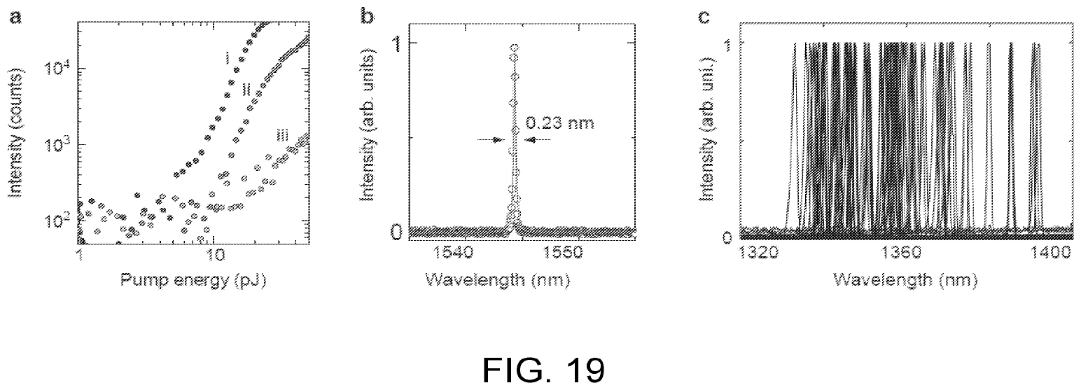

To characterize the angle dependence experimentally, we suspended microdisk LPs in a curable gelatin hydrogel (Matrigel, n=1.334) with fixed, random orientations and examined them under a laser-scanning confocal microscope combined with a pump laser (1064 nm wavelength, 3 ns pulse width, 2 MHz repetition, and 2.9 μm focal beam size) and a high-resolution spectrometer (Materials and methods). Upon optical pumping above their lasing threshold, the microdisk LPs exhibited single-mode emission with a sub-nm linewidth (FIG. 19). In FIG. 12e, the input-output curves of three representative LPs illustrate a distinct dependence on the orientation of the disks. Significantly more lasing light was collected from vertically oriented disks (FIG. 12e-i) than from flat ones (FIG. 12e-iii), as evidenced by the increased slope or “slope efficiency” of the input-output curve above threshold (˜10 pJ).

### Omnidirectional-Emitting Laser Particles (OLP)

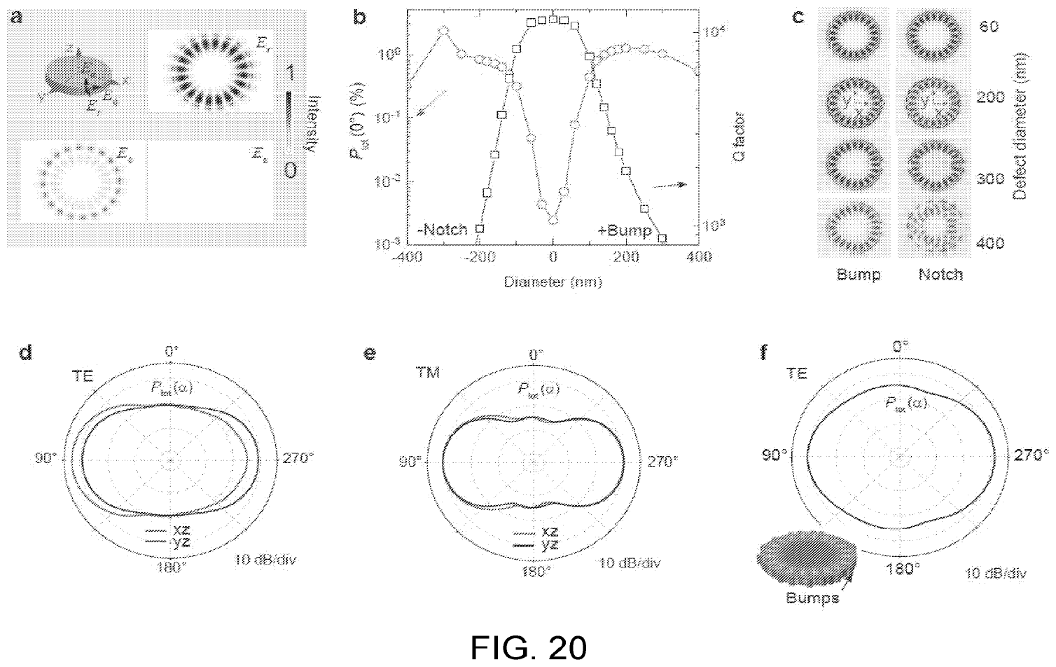

Although the output emission of a CLP is directional because of the innate geometry of its cavity structure, it is possible to transform the emission pattern by introducing perturbations. For example, surface roughness, boundary deformations or nanoscale scatterers could redirect part of the lasing light to directions out of the disk plane by elastic scattering (FIG. 12f). Because the electric field of the TE mode lies primarily in the plane of the disk (FIG. 20a), the Rayleigh-scattered pattern P_{sc}(α)∝1+cos²α has a maximum in the direction perpendicular to the disk plane (see below). Combining the predominantly in-plane emission from the microdisk P₀(α) and the predominantly out-of-plane scattering from the perturbations P_{sc}(α), the total pattern can be expressed as

$${P}_{tot} ( α ) = ( 1 - s ) \cdot {P}_{0} ( α ) + s \cdot {P}_{sca} ( α ) ' ( 1 - s ) \cdot {c}_{0} {sin}^{10} α + s \cdot {c}_{1} ( 1 + {cos}^{2} α ) , \qquad ( 4 )$$

where s represents the fraction of light scattered, c₀≈0.75 and c₁=0.21 (see below). Therefore, the min-max ratio becomes R=0.56 s/(1−0.72 s). The criteria of R>0.01 and R>0.1 are satisfied when s>0.018 and s>0.16, respectively. FIG. 12g shows an FEM simulation result for an LP with a single defect: a 200-nm semi-circular notch. The calculated Pₜₒₜ(α) is highly omnidirectional with R≈0.1 or −10 dB.

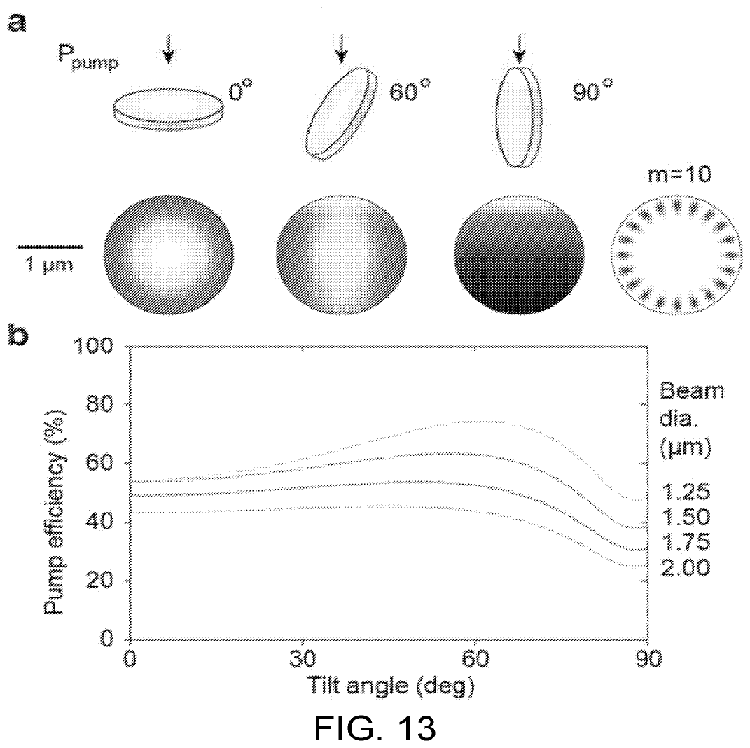

So far, we have considered the light collected from a microdisk. As the LP changes its orientation with respect to the excitation and collection optics (FIG. 12c), not only its emission but also the absorption of pump light in the LP will change. This can affect the threshold energy and, thereby, the total magnitude of output emission as a function of the tilt angle, contributing to the angle dependence of the collected light. To consider this effect, we calculated the amount of pump absorption. We used a geometrical model of light propagation in the microdisk with Fresnel reflection at the semiconductor-water interfaces and absorption in the material following a Lambert-Beer profile with an absorption coefficient of 1.75×10⁴ cm⁻¹. The pump beam was modelled with a Gaussian profile centered on its axis tilted at an angle α. FIG. 13a shows the spatial distribution of pump absorption at different disk orientation for a pump beam diameter of 1.5 μm at full-width-at-half-maximum (FWHM), which corresponds to our experimental condition. A pump efficiency ηₚ is defined as the overlap between the absorbed pump energy distribution p(α) and the mode profile |u|² of the cavity resonance, normalized by the same overlap integral in the case of an uniform pump distribution (ρ_{U}), η_{P}(θ)=∫_{cavity}ρ(θ)|u|² dV/∫_{cavity}ρ_{U}|u|² dV. The angle dependence of pump efficiency HM is shown in FIG. 13b. The lasing threshold, in the first approximation, is proportional to 1/np. For a beam size of 1.5 μm, the angular dependence of threshold energy is only 20%.

LPs with Surface Roughness

Nanometer-scale imperfections behave as Rayleigh scatterers and couple the resonant optical modes into far-field radiation. Conventional wisdom states that one ought to strive to reduce such imperfections during fabrication to maximize the quality factor of the laser cavity and thereby reduce the lasing threshold. We hypothesized that the sidewall roughness arising from reactive ion etching (RIE) can be intentionally introduced to reduce the emission directionality of microdisk LPs without significantly affecting lasing threshold.

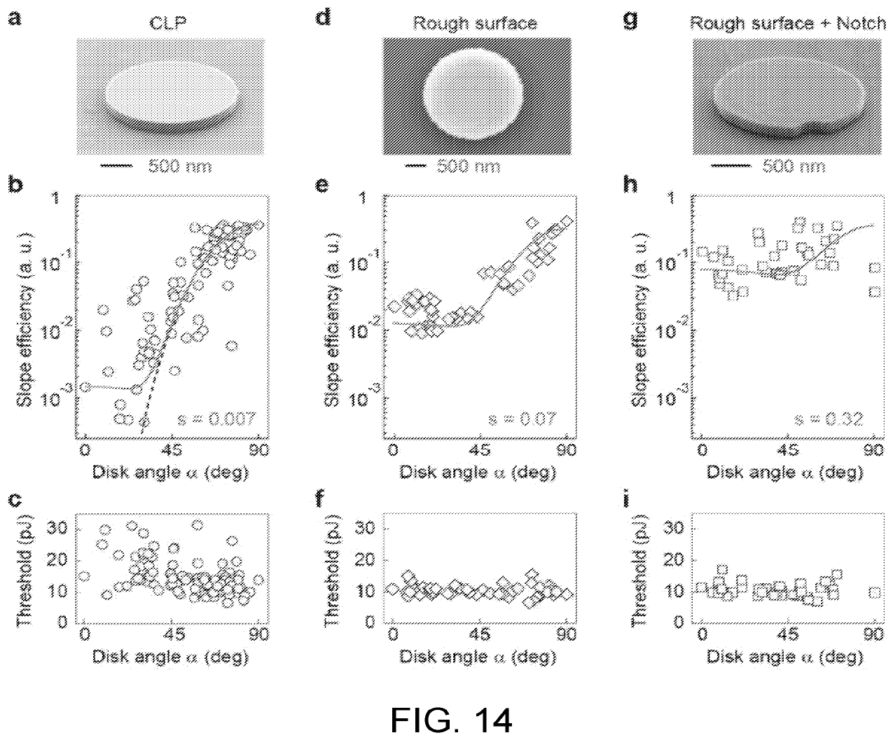

To investigate this approach, as a control group we measured a batch of CLPs with smooth sidewalls (FIG. 14a) embedded in a hydrogel. We measured the output intensity as a function of pump energy Pₚᵤₘₚ and obtained the slope efficiency A above threshold for each LP. The orientation angle α of each LP was extracted from optical bright-field images by ellipse-fitting the LPs' outline. The output power at each pump level can be readily obtained from the slope efficiency, using Pₜₒₜ(α)=Δ·(Pₚᵤₘₚ−Pₜₕ), where Pₜₕ is the threshold pump energy. If only the output intensity at one specific pump energy was recorded, the angle dependence analysis would be compounded by the difference in the pump threshold among the LPs. FIG. 14b shows the dependence of slope efficiency on the orientation angle α of 100 microdisks.

The fitting parameter s=0.007 with the scattering model (Eq. (4), green curve) reveals that the small imperfections on the LPs' surface only scatter 0.7% of the output emission on average and result in a small R≈0.004 or −24 dB for this CLP ensemble. This value of R is likely to be overestimated because Δ's less than 10⁻³ are not reliably measured due to the finite dynamic range of the spectrometer. Lasing thresholds were found to be 13±5 pJ, showing very low dependence on disk orientation (FIG. 14c). LPs with similar angles exhibit substantial variations in the slope efficiency and threshold. This was attributed to their slightly different sizes, causing variations in the laser wavelength across the gain bandwidth, and surface condition.

To increase the surface roughness, we fabricated LPs in the same way as the CLPs but using a different RIE chemistry that produces rougher sidewalls. This resulted in a batch of LPs with an azimuthal variation of ˜50 nm in the disk radius (FIG. 14d). These LPs showed reduced dependence of slope efficiency on a without degrading the lasing threshold as shown in FIGS. 14e and 14f, respectively. The curve fit yields s=0.07, meaning that the increased surface roughness is responsible for scattering 7% of the light, which results in an improved R from −24 to −14 dB.

LPs with Defined Boundary Defects

To further improve upon these results, we artificially introduced sub-wavelength semicylindrical defects with a negative (notch) or positive (bump) curvature. Simulation results illustrate that Pₜₒₜ(0°), which is almost entirely due to out-of-plane scattering from the boundary defect, increases with increasing defect size (FIG. 20b). When the defect size approaches half of the wavelength in the cavity medium, P_{sc}(0°) is close to saturation. The in-plane emission is slightly changed by the presence of a bump or notch (FIG. 20d). In both cases, we found that the boundary defects provide substantial out-of-plane scattering useful to reduce the dynamic range in the slope efficiency.

Experimentally we induced a notch or a bump with a diameter of 200 nm in microdisks using electron-beam lithography and roughness-inducing RIE processes. The resulting nanostructure is shown in FIGS. 14g and 21. To confirm the scattering effect of the boundary defect, we first measure these LPs on chip after partial undercut to create a supporting pillar. High-resolution maps of laser emission in the out-of-plane direction show that strong emission is generated in the vicinity of the boundary defects with a peak intensity >1000 counts (FIG. 21d). For comparison, a CLP with rough sidewalls shows a doughnut-like pattern, with emission arising primarily from the disk boundary with a peak intensity of ˜200 counts (FIG. 21d).

Notched LPs with rough sidewalls (FIG. 14g) were transferred into a hydrogel suspension to investigate their angle dependence. The measured slope efficiency showed a further reduced dependence on a as shown in FIG. 14h. Fitted with the scattering model, it is found that the combination of surface roughness and a boundary notch scatters about 32% (s=0.32) of the lasing light into other directions, resulting in a much improved min-max ratio R of 0.27 or −5.7 dB. Notched LPs with similar angles exhibit slightly larger variations in the slope efficiency, which is attributed to different laser mode number due to the nonuniformity in the disk size (FIG. 24c). In addition, since the threshold energy of the semiconductor lasers is mainly determined by the energy required to overcome the optical absorption and to reach material transparent absorption, even though the defect slightly reduces the radiation and scattering limited Q factor of the cavity (FIG. 20b), notched LPs have similar threshold to the CLPs, around 10±4 pJ, independent of the orientation angle α (FIG. 14i).

LPs Coated with a Scattering Layer (scLPs)

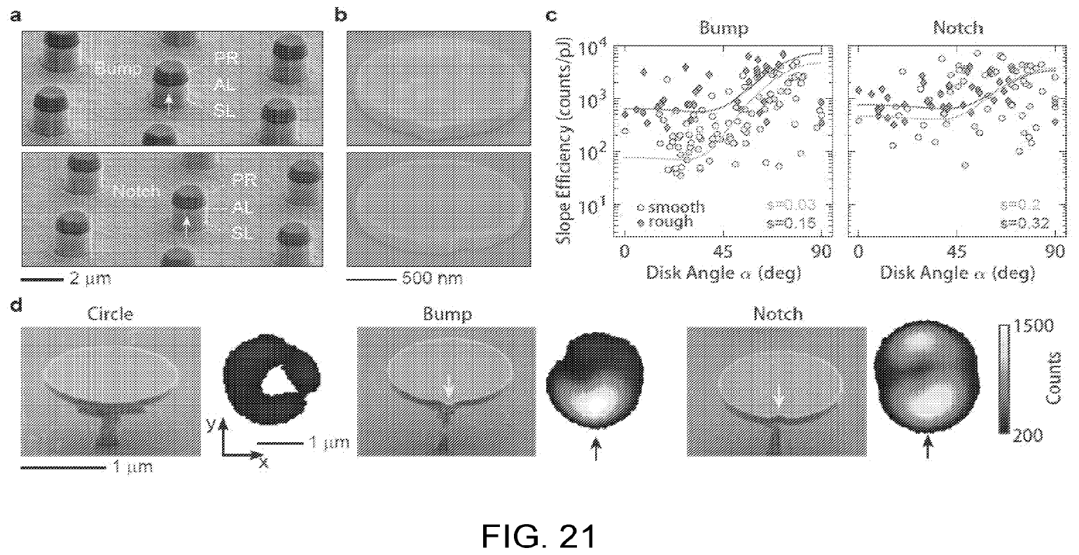

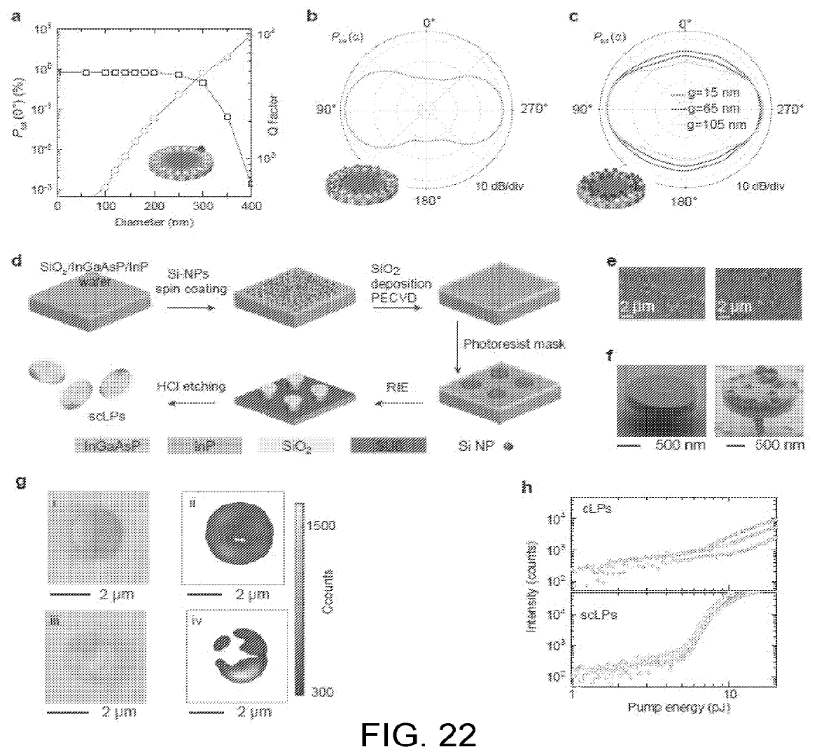

An alternative approach to achieving omnidirectional emission is to incorporate extra-cavity inhomogeneities. This could be realized by coating the microdisks with nanoparticles with large refractive index but low absorption loss. We chose silicon nanoparticles (SiNPs) due to their high refractive index of 3.48 and nearly zero imaginary part at near-infrared wavelengths. In a 3D FEM model, SiNPs were randomly placed on top of a microdisk and a thin silica coating layer was applied. The simulation result confirmed a strong light scattering effect of the monolayer of SiNPs (FIG. 22c). Although SiNPs are placed on only one side of the disk, the far-field radiation patterns exhibit considerable emission from both faces, implying that the coating of SiNPs on a single microdisk surface is sufficient to improve output omnidirectionality.

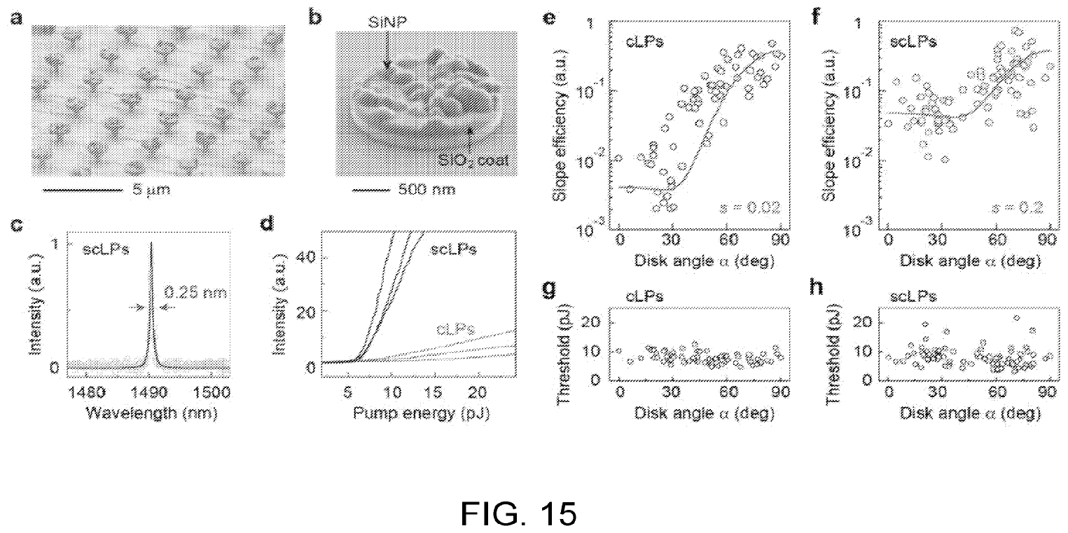

To realize this design, we devised a novel top-down fabrication method (FIG. 22d) for single-sided coating (FIG. 15a). This technique enabled SiNPs with size 30-50 nm to be placed at a distance of ˜15 nm from the InGaAsP microcavity by embedding them inside a silica cap attached to the cavity (FIG. 15b). We termed this specific type of OLP a ‘scatterer-coated laser particle’ (scLP). Importantly, unlike the semicircular notch OLPs mentioned earlier. scLPs do not rely on nanometer-scale boundary defects patterned using electron-beam lithography to generate scattered light. Therefore, they are amenable to high throughput production by UV lithography, rendering them suitable for practical applications.

In this experiment, an InGaAsP wafer with a gain bandwidth of ˜1400-1500 nm was used. The output emission of an scLP in hydrogel typically features a single peak with a FWHM of 0.25 nm (FIG. 15c), similar to that of control LPs (cLPs) that possessed a silica cap without embedded SiNPs. The lasing linewidth is determined by the carrier-induced index-modulation during pump pulses. The input-output curves in FIG. 15d measured on flat disks show that scLPs have larger slope efficiency compared with control LPs (the input-output curves plotted on a logarithmic scale are shown in FIG. 22h). cLPs suspended in hydrogel exhibited s=0.02 and R=0.011 (FIG. 15e). scLPs produced a higher degree of omnidirectionality with a fit parameter of s=0.2 and R=0.13 or −8.8 dB (FIG. 15f). Both scLPs and cLPs had similar threshold distributions (Pₜₕ=8±3 pJ) and showed no dependence on disk orientation (FIGS. 15g, 15h).

### Continuous Cell Tracking Using OLPs

To demonstrate the detection reliability of omnidirectionally-emitting LPs for cellular tracking, ˜10⁵ OLPs (scLPs) and CLPs (cLPs) were fabricated and separately transferred into cell media for HeLa cell coculture. Within 12 hours of incubation in vitro, both CLPs and OLPs were efficiently internalized by cells through the non-specific process of macropinocytosis. The orientation of loaded LPs was observed to vary continuously within the cells, resulting in random disk orientations at any given moment.

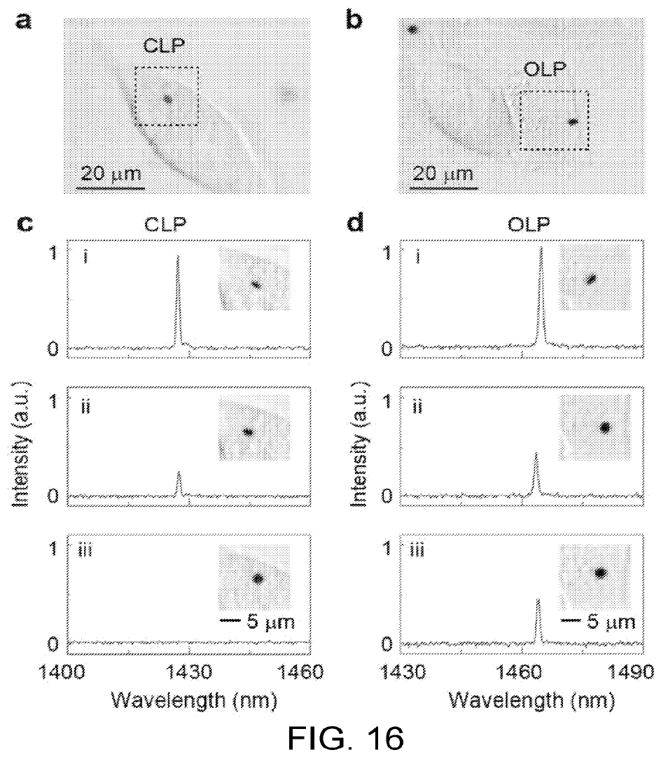

Using a custom-modified confocal microscope, bright-field images and lasing emission of LPs in cells were obtained as ground-truth data for tracking CLPs and OLPs in live Hela cells (FIGS. 16a, 16b). FIGS. 16c and 16d show output spectra at three time points from a CLP and an OLP, respectively, along with disk orientations. In each case, LPs were pumped under the same conditions. For both CLPs and OLPs, strong emissions were observed from the disks when seen edge-on, as expected (FIGS. 16c-i and 16d-i). However, for flat disks (FIGS. 16c-iii and 16d-iii), no laser peak was detected for the CLP, while a distinct lasing peak was observed for the OLP, with only a 50% reduction in power compared to the edge-on case.

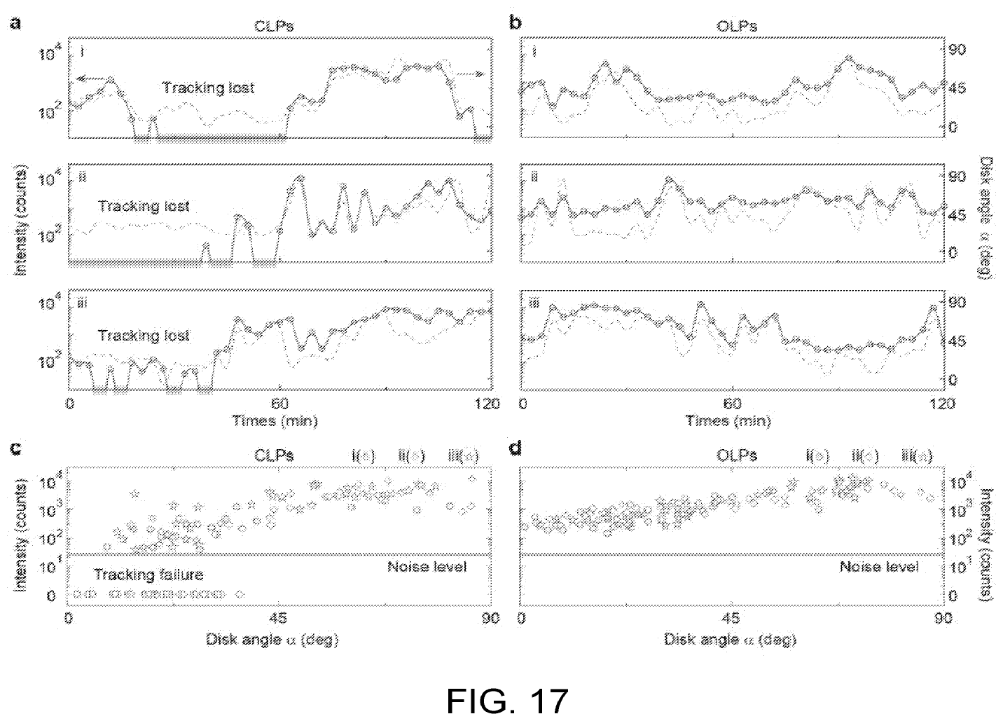

Next, we acquired time-lapse maps of several LPs of each type over a period of 2 hours. Because of the random-walk movement of LPs inside the cytoplasm, we scanned the focal plane in the z-direction to obtain Z-stack lasing maps and bright-field images every 3 min for 2 hours. Since LPs have single-mode emission with sub-nanometer linewidth (FIG. 19a), each LP was identified and tracked over time using a clustering algorithm based on the positional and spectral traces. For each LP, the integrated intensity of the lasing peak and orientation angle α was extracted from all spectral frames and bright-field images associated with the disk, respectively. FIGS. 17a and 17b show the time-lapse intensity traces of three typical CLPs and three OLPs, respectively. Whenever the orientation angle α became small (i.e. flat disks), the lasing peak intensities of the CLPs were overwhelmed by background noise (around 30 counts in our experiment), leading to frequent optical reading failure in cell tracking. In the 2-hour traces, the signal was lost in 28% of the frames (FIG. 17c). By contrast, OLPs could be continuously tracked over the entire 2 hours even when they rotated to small a (FIGS. 17b, 17d).

Thus various embodiments of highly omnidirectional LPs have been demonstrated which have a min-max ratio R˜−5.7 dB, low threshold, narrow linewidth, and single-mode lasing, which enable reliable cell tagging and continuous cell tracking. We expect OLPs to enhance tracking reliability in applications including deep tissue imaging, where intrinsic tissue scattering does not overcome the low signal collection efficiency from flat disks (See below). The scattering elements introduced at the boundary and flat surface were effective, directing up to 20-32% (s=0.20-0.32) of the collected laser emission to all directions.

To enable long-term operation in aqueous biological environments, the semiconductor LPs may need an additional protective layer. The simulated results in FIG. 24 reveal that the Pₜₒₜ(α) remain highly omnidirectional for OLPs with a protective silica coating layer. The notched OLP design could be improved by incorporating more than one boundary defect into the cavity design (FIG. 20f). Since state-of-the-art optical lithography offers a resolution of better than 150 nm, this method has the potential for low-cost, high-volume production of OLPs. scLPs are readily mass producible using optical lithography.

The high-brightness omnidirectional emission significantly improves the SNR of LPs, resulting in reliable spectral identification and spatial tracking without increasing exposure times. OLPs allow for continuous and high-speed tracking of single cells, which, combined with the massive spectral multiplexing capability of LPs, enables the study of cellular heterogeneity at the single-cell level in large-scale 3D biological specimens. Besides cell tracking, omnidirectionality will facilitate other applications of LPs, such as cellular and biochemical sensing and single-cell analysis in microfluidics, by ensuring high SNR.

### Fabrication and Transfer of LPs

Microdisk resonators were fabricated starting from epitaxially-grown III-V semiconductor wafers consisting of a 300-nm-thick buffer layer of undoped InP, a 200-nm-thick active gain material layer of InGaAsP, and a 100-nm-thick capping layer of undoped InP over an InP substrate.

Defect LPs by e-beam lithography: Microdisk lasers with nanoscale protrusions or indentations were fabricated on the semiconductor wafers. The patterns were defined by 100 keV electron-beam lithography (JBX6300FS, JEOL) on a negative-tone resist (SU-8, 50% dilution), and transferred to the semiconductor by reactive-ion etching (Oxford Plasmalab 100 ICP) using a mixture of chlorine and argon. The remaining resist was removed by oxygen and fluoroform plasma treatment, and ultrasonic agitation in an N-methyl-2-pyrrolidone-based organic solvent at elevated temperatures (Microposit Remover 1165, Dow Chemicals). Corresponding control samples with circular shapes were fabricated by the same method. For the on-pillar disks, the supporting pillars were undercut by wet chemical etching in diluted HCl. During this last step, the capping layer is also removed. Samples with intentional surface roughness were fabricated following a similar process flow, but using hydrogen bromide chemistry during RIE.

Control LPs (cLPs) and scLPs by optical lithography: First, the InP capping layer was removed by etching in 3:1 HCl:H₂O for 10 s. Cleaning of the surface was then performed using acetone, isopropyl alcohol (IPA) and water followed by O₂ plasma (30 s, 100 W, 40 sccm O₂) (SCE 106, Anatec Ltd). Next, 15 nm of SiO₂ was deposited by plasma-enhanced chemical vapor deposition (PECVD) (Surface Technology Systems). Silicon nanoparticles (30-50 nm, US Research Nanomaterials, Inc) in IPA were filtered using a centrifuge filter (pore size: 450 nm), and particle aggregations were broken up by a probe sonicator (Fisher Scientific). Immediately before spinning the silicon nanoparticles, the individual chips were cleaned using O₂ plasma (60 s, PE-25, Plasma Etch Inc.). The newly deposited silica layer was wetted with IPA and spread uniformly across the chip at a spin speed of 2000 rpm for 45 s (Laurell Technologies Corporation). 20 μl of Si nanoparticles suspended in IPA was dynamically dispensed at 600 rpm before increasing the spin speed to 3000 rpm where it was held for a time of 120 s, during which the IPA fully dried. During this spin-coating step, silicon nanoparticles aggregates approximately a hundred nanometers in scale form on the wafer surface (FIG. 22e).

Next, a second 250-nm-thick layer of SiO2 was deposited by PECVD to fully incorporate the nanoparticles into the silica shell. The surface was then cleaned using the O₂ plasma (120 s, Matrix 105). To enhance photoresist adhesion to the SiO2 film, an adhesion promoter (Omnicoat MicroChem) was used before spin-coating (Headway Research, Inc.) the surface with a 3 μm-thickness layer of photoresist (SU8-2002 MicroChem). Soft baking procedures followed the manufacturer's guidelines. The 2.5 μm-diameter circles of SU8 photoresist (Density: ˜3.2 million/cm²) were then defined using a projection exposure tool (MLA150, Heidelberg Instruments) at a dose of 1500 mJ/cm² at a wavelength of 375 nm. A two-step post-exposure bake was used, consisting of 60 s at 65° C. followed by 180 s at 95° C. on a contact hotplate. The resist was developed for 60 s in SU8 Developer (MicroChem). To smoothen the sidewalls of the resist and harden it for dry etching, a further bake at 190° C. for 10 minutes was performed on a contact hotplate. The residual photoresist was removed using a 90 s descum at 100 W, 40 sccm O₂ (SCE 106, Anatec Ltd). Next, inductively coupled reactive ion etching (ICP-RIE) using a fluorine-based chemistry was performed (Surface Technology Systems) to define columns consisting of Si nanoparticles embedded in the silica film. Any remaining SU8 resist was subsequently removed using O₂ plasma ashing (Matrix 105) for 10 minutes at 220° C. The Si/SiO2 columns were used as a hard mask for an III-V ICP-RIE process which etched depth of approximately 1 μm using a chlorine-based chemistry (PlasmaPro 100 Cobra 300, Oxford Instruments).

The corresponding control samples with a silica-capping layer were prepared with the same method without spinning the silicon nanoparticles. For completely detaching the microdisks, the substrates were wet-etched face down in 3:1 HCl:H₂O solution inside a 1 μm pore centrifuge filter for 30 s and filtered thoroughly by at least 3 repeated cycles of centrifugation and resuspension (via ultrasonication) using ultrapure water.

### Optical Characterization

For optical characterizations and imaging of microdisks, a laser-scanning LASE microscope modified from a commercial confocal microscope (Olympus FV3000) was used. A pump laser (Spectra Physics VGEN-ISP-POD, 1060-1070 nm, pulse duration 3 ns, repetition rate 2 MHZ) with the output power controlled by an acoustic optical modulator and measured by an external Photodetector, was coupled to a side port of the laser-scanning unit of the microscope. The day-to-day variation in the measurement of absolute pump power is up to 30%. The emission from microdisks was collected from the same port and relayed by a dichroic mirror to a NIR spectrometer using an InGaAs linescan camera (Sensor Unlimited 2048L). 100 lines/mm grating (0.6-nm resolution over 1150-1600 nm, exposure time: 0.1 ms) was used for threshold characterization, and a 500 lines/mm grating was used for high-resolution linewidth characterization (0.2-nm resolution, 150-nm span, exposure time: 0.1 ms). In both cases, a NIR-optimized, 20×, 0.45-NA objective (Olympus IMS LCPLN20XIR) were used. The high-resolution lasing mapping images were acquired with a 100×, 0.85-NA objective (Olympus IMS LCPLN100XIR) and the NIR spectrometer with the 100 lines/mm grating (0.6-nm resolution over 1150-1600 nm, exposure time: 0.1 ms).

### Numerical Simulation of Far-Field Pattern

The modeling of passive microdisk resonance was conducted via a series of three-dimensional finite-element simulations (COMSOL Multiphysics 5.3a). We set the refractive indices of the microdisk and hydrogel to be 3.445 and 1.334 respectively. The optical absorption of bulk semiconductor material and laser gain are not considered here. The shape and size of the disk agree with that of the semiconductor laser particles we used in our experiment (obtained by SEM). The thickness of the disk is 200 nm, the diameter of defect LPs and corresponding control LP made by e-beam lithography is 2 μm, and the diameter of scLPs and corresponding control LPs are 2.5 μm. The simulation region was set with perfectly matched layer boundary conditions in all directions. The distance to the perfectly matched layer boundaries as well as the meshing size were chosen after a series of convergence tests. We used the eigen-frequency study (Physics: Radio Frequency, frequency domain) and the far-field domain plug-in to calculate the far-field pattern of WGM mode. The randomly distributed nanoparticles for scLPs were generated by an application-builder module. The calculated intensity pattern (|E_{far}(θ,φ)|²) was exported, and a MATLAB script was used to calculate output pattern through the integration over the acceptance solid angle Ω=2π[1−cos(sin⁻¹(NA/n))]=0.37 steradian (Eq. (3)). Finally, the output pattern Pₜₒₜ(α) was normalized by the total output energy.

### Cell-Culture Experiments

HeLa human cervical cancer cells (ATCC) were cultured and maintained with Dulbecco's modified Eagle medium (DMEM) supplemented with 10% (v/v) fetal bovine serum (FBS) and 1% (v/v) penicillin-streptomycin. Cells were seeded in 8 well-chambered glass dishes (Cellvis) at a density of 15,000 cells/cm². After 24 hours, 60,000 scLPs were added to one of the culture wells, and 60,000 control LPs were added to a control well, along with the requisite quantity of 10×PBS to ensure isotonicity of the final solutions. After 1 hour, the cell media was aspirated and replaced with a fresh volume. The cells were then incubated (Thermo Scientific Heracell 240i) with the LPs at 37° C. and 5% CO₂ for 8 hours to give sufficient time for LP uptake. During imaging, cells were incubated using a microscope stage top incubator (Tokai Hit).

Cell tracking experiments were performed by acquiring time-lapse data every 3 minutes over a total period of 2 hours. During the measurement, cells were placed in a temperature-controlled cell-culture incubator. Six regions were defined: three from the scLPs well and three from the control well. Each region, consisting of 320×320×7 voxels corresponding to a volume of 212×212×21 μm³, was scanned with an NIR pump laser (Spectra Physics VGEN-ISP-POD, pulse duration 3 ns, repetition rate 2 MHz, pulse energy 160 pJ), using a pixel dwell time of 20 μs. Brightfield images were recorded simultaneously with the acquisition of spectral LP emission. For each microdisk, the integrated intensity of the lasing peak was calculated for all spectral frames associated with the disk. Orientations were obtained by analyzing the brightfield images using ImageJ and the orientation angle was then associated with the maximum integrated intensity of each disk's lasing peak.

Fluorescent imaging was obtained by washing the cells three times with PBS, fixed with 4% paraformaldehyde/PBS (Fisher Scientific), permeabilized with 0.1 Triton X-100/PBS (Fisher Scientific) and incubated with AlexaFluor 594-Phalloidin (Thermo Fisher) for actin staining and NucBlue Fixed Cell Stain (Thermo Fisher Scientific) for nuclear staining, following manufacturer guidelines.

### Far-Field Modeling of WGM Resonance

A scalar diffraction theory of light emanating from a microdisk of radius R into the far-field is given in the spherical coordinates (r, θ, φ), as:

$${\vert {E}_{far} ( θ , ϕ ) \vert}^{2} ∝ \frac{{cos}^{2} ϕ}{{r}^{2}} {\vert \frac{F ( k cos θ )}{{H}_{m}^{( 2 )} ( lkR sin ϕ )} \vert}^{2} , \qquad ( 5 )$$

where k=nω/c is the wave number, w is the angular frequency, n is the refractive index of external environment of the microdisk, F is the Fourier transform of the near-field distribution f(z) on the cylindrical surface ρ=R in cylindrical coordinate (ρ, θ, z), and H⁽²⁾ₘ is the Hankel function of the second kind.

Considering a typical semiconductor microdisk laser (refractive index 3.445, radius R=1 μm, and thickness of 200 nm), the m=10th-order TE WGM at the resonant wavelength of 1270 nm is obtained by a 3D FEM simulation (FIG. 18a). For simplicity, the near-field distribution f(z) is approximated by a Gaussian function with a FWHM equal to the disk thickness 200 nm. The calculated far-field intensity in FIG. 18e illustrates that its divergence angle (i.e. FWHM) is about 32°. The theoretical result is in good agreement with the result calculated by 3D FEM simulation, and can be approximated by |E_{far}(θ)|²/sin¹⁸(e) (FIG. 26a). The deviation when the normalized |E_{far}(θ)|²<10⁻⁵ is attributed to the limited accuracy in numerical simulation or the Gaussian approximation of near-field distribution.

Experimentally, the output emission is collected by a lens with a finite numerical aperture (NA). The power collected from a microdisk that is tilted with respect to the viewing axis by an angle α is given by

$${P}_{signal} ( α , NA ) ∝ {\int }_{Ω} {\vert {E}_{far} ( θ , ϕ ) \vert}^{2} sin θ d θ d ϕ , \qquad ( 6 )$$

where the integration is performed over the solid angle defined by a cone with half angle α sin(NA/n) centered on a. FIG. 18f shows the dependence of P_{signal} on the tilted angle α of the disk (FIG. 18f). The theoretical result of P_{signal} is in good agreement with the result calculated by 3D FEM simulation, which could be approximated by P_{signal}/sin¹⁰(α) for NA=0.45 (FIG. 26b). Note that, when standing waves are formed by two counter propagating WGMs, the lobed azimuthal structure in the far-field intensity profile is approximately averaged out provided the collection NA is greater than 0.5πn/m, or >0.2 for m=10 (FIG. 18g).

The ratio R of the minimum and maximum intensities as a function of NA

To quantify the angle dependence of P_{signal}, we calculate the ratio R of the minimum and maximum collected powers from the result of Eq. 6. Note that R is a strong function of the NA of light collection. FIG. 27 describes the dependence of R for a conventional LP as a function of NA/n. For high NA>0.7, we find R=110 (NA/n−1) dB.

In this work, we consider a LP with R>0.01 as being omnidirectional, and R>0.1 as highly omnidirectional. These conditions could be achieved with a CLP when NA>1.1 and NA>1.2, respectively. Using such high NA, however, may not be allowed in certain instruments, nor be a desirable solution because its diffraction-limited volume at the focus would become much smaller than the size of an LP, reducing the collection efficiency and causing intensity variations depending on the focal position. For LPs with a size of D and wavelength of λ, the maximum NA without significantly losing collection efficiency is ˜λ/D. For D=2 μm and λ=1270 nm, the collection NA should be less than 0.64. As heuristic approximates, for NA<0.7 we find P_{signal}(a, NA)/|sin α|^{q}, where q≈18-18*NA and R<−60 dB.

### Scattering Model

The nanoscale surface roughness, boundary deformations or external particles could scatter part of emitted and intracavity light to directions out of the disk plane by elastic scattering. The Rayleigh-scattered intensity P_{sc}(α) should have the maximum when α=0° and the minimum at 90° because the electric field of the TE mode is polarized primarily in the plane of the disk (FIG. 20a). Integrating the random dipole-induced scattered light of the TE mode over the entire surface of a microdisk, the scattering pattern could be heuristically described as the Rayleigh scattering profile for unpolarized light:

$${\vert {E}_{sc} ( θ , ϕ ) \vert}^{2} ∝ 1 + {cos}^{2} θ , \qquad ( 7 )$$

While a conventional LP predominantly emits in the radial direction, scattering predominantly radiates orthogonally to this plane about the θ=0° axis, which we define as the +z axis. Notice that we can rewrite the angle dependence of the scattering radiation in terms of the spherical unit vector \vec{r}=sin θ cos φ\vec{x}+sin θ sin φ\vec{y}+cos θ\vec{z}.

$${\vert {E}_{sc} ( \vec{r} ) \vert}^{2} ∝ 1 + {( \vec{r} \cdot \vec{z} )}^{2} , \qquad ( 8 )$$

To account for rotation of the microdisk LP, we use a standard rotation matrix [symbol] to rotate \vec{r} about the x-axis by some angle α to yield a new vector

$${\vec{r}}_{α} = ( α ) \vec{r} = sin θ cos ϕ \vec{x} + ( cos α sin θ sin ϕ - sin α cos θ ) \vec{y} + ( sin α sin θ sin ϕ + cos α cos θ ) \vec{z} \qquad ( 9 )$$

Therefore, we expect the number of scattered photons collected by our optical setup for a disk tilted from horizontal by an angle α to be given by

$${P}_{sc} ∝ {\int }_{0}^{{θ}_{0}} {\int }_{0}^{2 π} {\vert {E}_{sc} ( θ , ϕ ) \vert}^{2} sin θ d θ d ϕ , \qquad ( 10 )$$

where θ₀ defines the collection angle of the objective. Evaluating this integral gives

$${P}_{sc} ( α ) ∝ \frac{π}{24} ( cos 2 α [ 3 cos {θ}_{0} - 3 cos 3 {θ}_{0} ] - 63 cos {θ}_{0} - cos 3 {θ}_{0} + 64 ) \approx \frac{{πθ}_{0}^{2}}{2} ( 3 + cos 2 α ) = {πθ}_{0}^{2} ( 1 + {cos}^{2} α ) \qquad ( 11 )$$

where going from the first to second line we have used the paraxial approximation cos x=1−x²/2. This suggests that a sinusoidally quadratic emission pattern retains the general form of its angle dependence when its emission is collected by a paraxial optical system, i.e.

$${P}_{sc} ( α ) ∝ 1 + {cos}^{2} α \qquad ( 12 )$$

Combining the in-plane emission from the microdisk and the out-of-plane scattering from the perturbations, the total pattern of OLP can be expressed as

$${P}_{tot} ( α ) = ( 1 - s ) \cdot {P}_{0} ( α ) + s \cdot {P}_{sc} ( α ) , \qquad ( 13 )$$

where P₀(α) is the intrinsic emission of the lasing mode in the perturbed LP, P_{sc}(α) denotes the intensity pattern arising from scattering objects, and s represents the fraction of light scattered. If the perturbation to the lasing mode is small, P₀(α) would be close to P_{signal}. The Rayleigh-scattered intensity P_{sc}(α) should have the maximum at α=0° and the minimum at 90°. The original and scattered profiles are thus complementary and could constitute omnidirectional emission for sufficiently large s. With appropriate normalization factors, Eq. (13) may be written as, for NA<0.7:

$${P}_{tot} ( α ) ∝ ( 1 - s ) \cdot {c}_{0} {\vert sin α \vert}^{q} + s \cdot {c}_{1} ( 1 + {cos}^{2} α ) , \qquad ( 14 )$$

where c₀=∫^{4π} sin¹⁸θ dΩ/∫^{4π} sin^{q}θ dΩ≈0.75 for NA=0.45 (q=10) and c₁=∫^{4π} sin¹⁸θ dΩ/∫^{4π} (1+cos²θ) dΩ≈0.21, c₁/c₀=∫4π sin^{q}θ dΩ/∫^{4π} (1+cos²θ) dΩ≈0.28. Putting these values into Eq. (14), we find the min-max ratio to be:

$$R \approx \frac{0.56 s}{1 - 0.72 s} . \qquad ( 15 )$$

The criteria of R >0.01 and R >0.1 are satisfied when s >0.018 and s >0.16, respectively.

scLPs Obtained by Chemical Functionalization

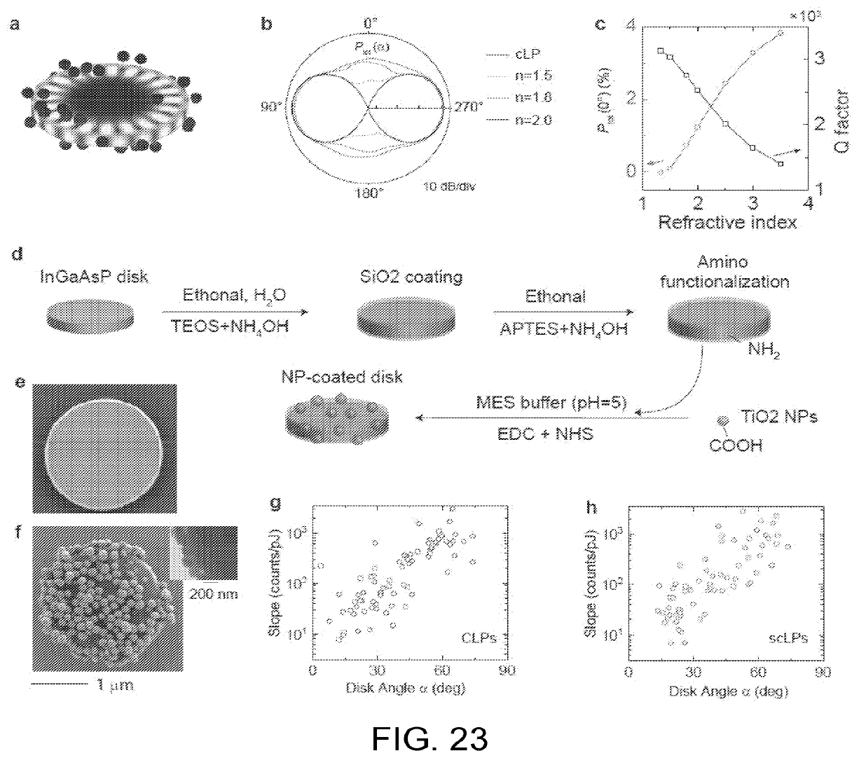

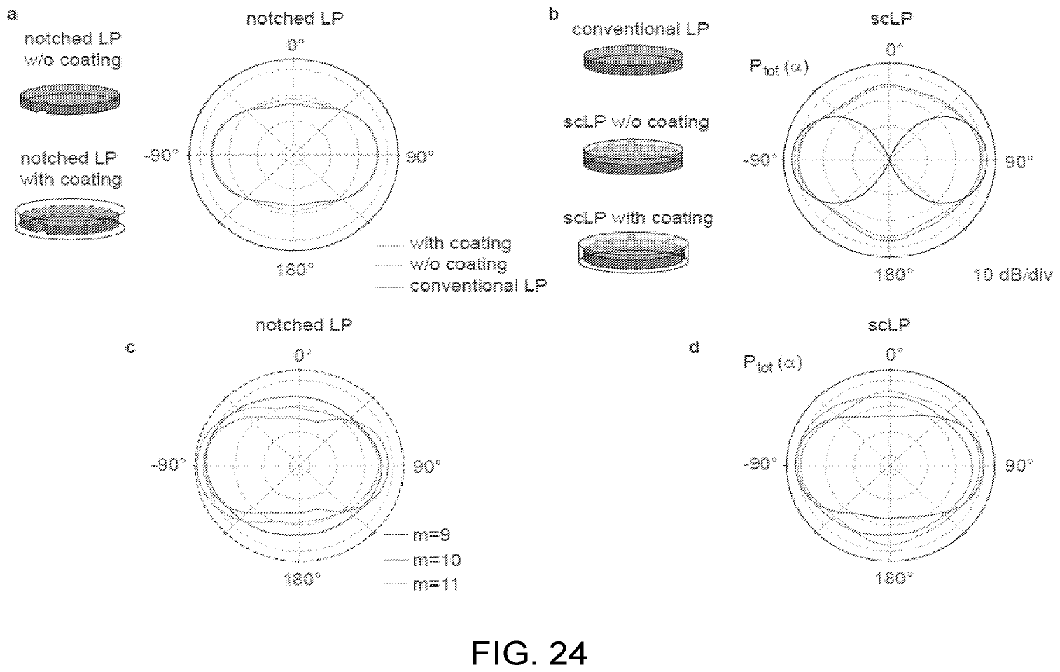

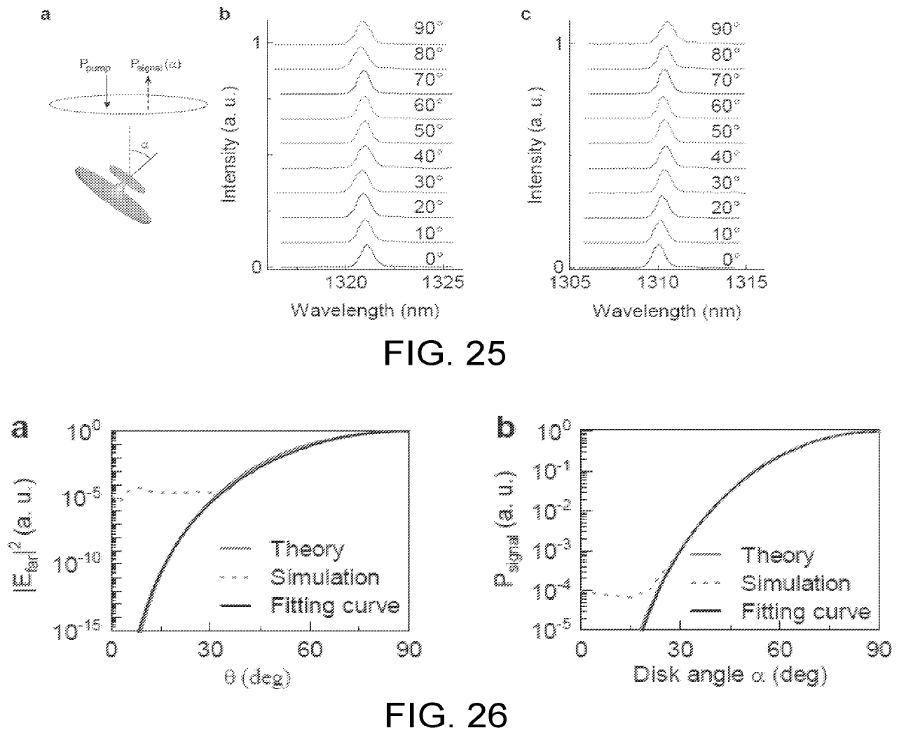

We have developed silica coating on LPs by a modified Stober method. Therefore, we can also adsorb scatterers onto LP templates by a chemical bonding method, which has widely been used to conjugate various nanoparticles and biomolecules onto silica surface with chemical modifications. Firstly, a numerical simulation was performed to illustrate the feasibility of this approach. As an example, 47 nanospheres with a diameter of 200 nm are randomly distributed on the surface of a LP with a 50-nm-thick silica gap, as shown in the device models (FIG. 23a). The simulated Pₜₒₜ(α) (FIG. 23b) of the TE mode shows a distinct emission in the vertical direction. The vertical output becomes larger with increasing refractive index of the nanoparticles, while the scatterers do not dramatically degrade the Q-factor of the cavity (FIG. 23c).

In the experiment, we used commercially-available TiO₂ nanospheres functionalized with carboxyl groups as scatterers on silica coated LPs. The scLP production process is described in FIG. 23d, and involves conjugating a great number of carboxyl TiO₂ particles onto the amino-functionalized silica surface around LPs through amide bond formation. As a result, hundreds of TiO₂ particles with a diameter of about 200 nm were coated on the surface of LPs (FIG. 23f). Measurements of scLPs suspended in the hydrogel show no distinct improvement in the dynamic range R. with both scLPs and control LPs failing to meet the omnidirectionality criterion R >0.01 (FIGS. 23g, 23h). This is attributed to the low refractive index (<1.8) of amorphous TiO₂ nanoparticles and the large silica gap distance (˜50 nm) between TiO₂ particles and semiconductor disk surface. Although the TiO₂ nanoparticles have no distinct scattering effect in hydrogel, this developed chemical bonding method could be suitable for high-refractive-index nanoparticles as scatterers on LPs.

Methods of scLPs Obtained by Chemical Functionalization.

Silica coating: Silica coating of the microdisks was performed by a modified Stober process. A typical silica coating with a thickness of 50 nm is as follows: Microdisks (about 105 LPs/ml) were suspended in 670 μl of ethanol:H₂O solution (80 v/v % ethanol). Next, 60 μl of 40 mM tetraethyl orthosilicate (TEOS) in ethanol, and 45 μl of ammonium hydroxide solution (28 v/v % NH₄OH) were added, and the microdisk solution was shaken vigorously at 1,400 rpm. for 1 h at room temperature. To harden the silica shell and improve chemical stability, the temperature was increased to 70° C. and the solution was mixed for an additional 2-12 hours. Then, the microdisks were filtered out by a transwell centrifuge filter with a pore size of 1 μm. To remove the small silica nanoparticles, the microdisks in the transwell centrifuge filter were sonicated for 5-10 mins in DI water and thoroughly centrifuge-filtered 3-4 times. Amino functionalization: The silica-coated microdisk was suspended in 950 μl of ethanol solution. Then, 40 μl of NH₄OH and 10 μl of (3-aminopropyl)-triethoxysilane (APTES) were added, and the microdisk solution was shaken vigorously at 1,400 r.p.m. overnight at room temperature. The suspension of microdisks was then transferred to a 1 μm-pore centrifuge filter, and filtered thoroughly by at least three repeated cycles of centrifugation and resuspension (via ultrasonication) using ethanol and DI water.

TiO₂ nanoparticle coating: Carboxylated titania nanoparticles with a diameter of 200 nm (1010 nanoparticles/ml, Microspheres-Nanospheres company) in water was firstly filtered using a centrifuge filter with a pore size of 1 μm to remove the aggregated nanoparticles. Carboxylated TiO₂ particles and amino-functionalized microdisks were separately dispersed in buffer solution (300 μl). Buffer solution refers to MES aqueous solution (10 mM, pH=5). A microdisk solution was then added to the TiO₂ particles solution with ultrasonic treatment and placed on a shaker for 5 minutes. A buffer solution (200 μl) containing N-(3-dimethylaminopropyl)-N′-ethylcarbodiimide Hydrochloride (EDC, 25 mg) and N-hydroxysuccinimide (NHS, 25 mg) was added and placed on a shaker for another 3 hours. Finally, the suspension of nanoparticle-coated microdisks was then transferred to a 1 μm-pore centrifuge filter, and filtered thoroughly by at least five repeated cycles of centrifugation and resuspension (via ultrasonication) using DI water.

Effect of deep tissue scattering on angle-dependent collection efficiency.

In applications in which microdisk LPs are imaged deep within biological tissues, intrinsic scattering of light from the tissue itself may affect the angle-dependent collection efficiency of the LP. To investigate this phenomenon, an open-source Monte-Carlo simulation platform was used. By defining a directional emitter of the theoretical form |E_{far}(θ)|²=sin¹⁸(e) using custom C code, we were able to simulate disk emission for a variety of angles between θ=0 and θ=90°. The tissue scattering properties were chosen to be consistent with typical values for brain tissue at 1270 nm with a scattering coefficient μₛ=72 cm⁻¹ and anisotropy g=0.9. The absorption coefficient μₐ=1.1 cm⁻¹ was set to be that of water.

FIG. 28a shows 100 sample photon paths for a microdisk located at (x, y, z)=(0, 0, 0.3 mm) viewed along the y-axis with angle α=0 (i.e. a flat disk). The surface of the tissue is located at the z=0 plane. FIG. 28b shows the analogous case but for a vertically oriented disk α=90°. To investigate the role of angle dependence on collection efficiency in scattering tissue, a 3 cm×3 cm×3 cm simulation volume was used. Collection was simulated by saving the paths of between 0.6×10⁶ and 10⁶ photons for a variety of starting disk tilt angles and starting depths. To determine whether photons leaving the tissue were successfully collected, a custom Matlab script simulated lossless propagation between the objective lens and the spectrometer's linescan detector with a pixel size of 10 μm (along the array) by 210 μm (height). Perfect NA matching between the 0.45 NA objective and 0.13 NA collection aperture of our spectrometer was assumed. The internal spectrometer magnification was set to unity and the slit size at 20 μm and pixel height at 210 μm.

The results are shown in FIG. 28c. Even at depths up to 500 μm, the collection efficiency of a vertically oriented disk far exceeds that of a flat disk. Fitting curves for each initial depth is shown, resulting in estimates of s=0.004, s=0.006 and s=0.01 corresponding to R=−26.5 dB, R=−24.7 dB, and R=−22.5 dB for depths of 100 μm, 300 μm, and 500 μm respectively. At these depths, collection of light from the microdisk is still highly angle-dependent and does not fulfill our goal of R<0.01.

It will be appreciated by those skilled in the art that while the disclosed subject matter has been described above in connection with particular embodiments and examples, the subject matter is not necessarily so limited, and that numerous other embodiments, examples, uses, modifications, and departures from the embodiments, examples, and uses are intended to be encompassed by the claims attached hereto. The entire disclosure of each patent and publication cited herein is hereby incorporated by reference, as if each such patent or publication were individually incorporated by reference herein.

Various features and advantages are set forth in the following claims.

What is claimed is:

1. A laser microparticle for generating laser light with high omnidirectionality, comprising:
an optical cavity comprising an active gain material capable of supporting one or more lasing cavity modes; and
an optical scattering element which is incorporated into the optical cavity and configured to change a radiation pattern of the one or more lasing cavity modes to increase an omnidirectionality of the radiation pattern.

2. The laser microparticle of claim 1, wherein the size of the microparticle is less than 10 μm in each dimension.

3. The laser microparticle of claim 1, wherein the omnidirectionality of the radiation pattern is indicated by an omnidirectionality index,
wherein the laser microparticle has an omnidirectionality index greater than 0.10.

4. The laser microparticle of claim 1, wherein the omnidirectionality of the radiation pattern is indicated by an omnidirectionality index,
wherein the laser microparticle has an omnidirectionality index greater than 0.25.

5. The laser microparticle of claim 1, wherein the scattering element comprises a nanometer-scale roughness on the surface of the optical cavity.

6. The laser microparticle of claim 1, wherein the scattering element comprises at least one of a bump or a notch on the surface of the optical cavity.

7. The laser microparticle of claim 6, wherein the bump or the notch has a radius in a range of 50 nm to 400 nm.

8. The laser microparticle of claim 7, wherein the bump or the notch has a radius of 100 nm.

9. The laser microparticle of claim 1, wherein the scattering element comprises a nanoparticle.

10. The laser microparticle of claim 9, wherein the nanoparticle comprises high a refractive-index material.

11. The laser microparticle of claim 10, wherein the nanoparticle comprises at least one of silicon or a III-V semiconductor.

12. The laser microparticle of claim 9, wherein the nanoparticle has a diameter in a range of 30 nm to 200 nm.

13. The laser microparticle of claim 9, wherein the scattering element comprises a plurality of nanoparticles.

14. The laser microparticle of claim 13, wherein the plurality of nanoparticles comprises 5 to 50 nanoparticles per laser microparticle.

15. The laser microparticle of any one of claims 1-14, wherein the active gain material comprises a semiconductor.

16. The laser microparticle of any one of claims 1-14, wherein the optical cavity comprises a microdisk.

17. The laser microparticle of claim 16, wherein the scattering element comprises a feature layered axially with respect to the microdisk, wherein the feature has a different radius than the microdisk.

18. A microparticle for generating laser light comprising:
an optical cavity comprising a microdisk including an active gain material capable of supporting one or more lasing cavity modes; and
an optical scattering element associated with the optical cavity and configured to change a radiation pattern of the one or more lasing cavity modes to increase omnidirectionality of light introduced into the optical scattering element.

19. The microparticle of claim 18, wherein the microdisk has a diameter of less than 10 μm.

20. The microparticle of claim 18, wherein the omnidirectionality of the radiation pattern is indicated by an omnidirectionality index,
wherein the laser microparticle has an omnidirectionality index greater than 0.10.

21. The microparticle of claim 18, wherein the omnidirectionality of the radiation pattern is indicated by an omnidirectionality index,
wherein the laser microparticle has an omnidirectionality index greater than 0.25.

22. The microparticle of claim 18, wherein the optical scattering element comprises a modification of a surface of the microdisk.

23. The microparticle of claim 22, wherein the modification of the surface comprises a modification of an edge of the microdisk.

24. The microparticle of claim 23, wherein the modification of the edge of the microdisk comprises a nanometer-scale roughness in a surface of the optical cavity.

25. The microparticle of claim 23, wherein the modification of the edge of the microdisk comprises at least one of a bump or a notch on the edge of the microdisk.

26. The microparticle of claim 25, wherein the bump or the notch has a radius in a range of 50 nm to 400 nm.

27. The microparticle of claim 26, wherein the bump or the notch has a radius of 100 nm.

28. The microparticle of claim 22, wherein the modification of the surface of the microdisk comprises a nanoparticle coupled to the microdisk.

29. The microparticle of claim 28, wherein the nanoparticle comprises a high refractive-index material.

30. The microparticle of claim 29, wherein the high refractive-index material comprises at least one of silicon or a III-V semiconductor.

31. The microparticle of claim 28, wherein the nanoparticle has a diameter in a range of 100-200 nm.

32. The microparticle of claim 28, wherein the microdisk includes between 10 and 50 nanoparticles.

33. The microparticle of claim 18, wherein the modification of the surface of the microdisk comprises a feature layered axially with respect to the microdisk,
wherein the feature has a different radius than the microdisk.

34. The microparticle of any one of claims 18-33, wherein the active gain material comprises a semiconductor.

35. A laser generating microparticle comprising:
an optical cavity;
an active gain material arranged in the optical cavity and configured to operate according to one or more lasing cavity modes; and
an optical scattering element associated with the optical cavity and configured to change a radiation pattern of the one or more lasing cavity modes to direct light in a plurality of different directions when the light is introduced into the optical scattering element.

36. The microparticle of claim 35, wherein the microparticle has a diameter of less than 10 μm.

37. The microparticle of claim 35, wherein the omnidirectionality of the radiation pattern is indicated by an omnidirectionality index,
wherein the laser microparticle has an omnidirectionality index greater than 0.10.

38. The microparticle of claim 35, wherein the omnidirectionality of the radiation pattern is indicated by an omnidirectionality index,
wherein the laser microparticle has an omnidirectionality index greater than 0.25.

39. The microparticle of claim 35, wherein the scattering element comprises a nanometer-scale roughness formed on a surface of the microparticle surrounding the optical cavity.

40. The microparticle of claim 35, wherein the scattering element comprises at least one bump or notch on a surface of the microparticle surrounding the optical cavity.

41. The microparticle of claim 40, wherein the bump or notch has a radius in a range of 50 nm to 400 nm.

42. The microparticle of claim 41, wherein the bump or notch has a radius of 100 nm.

43. The microparticle of claim 35, wherein the scattering element comprises a nanoparticle.

44. The microparticle of claim 43, wherein the nanoparticle includes at least one of silicon or a III-V semiconductor.

45. The microparticle of claim 43, wherein the nanoparticle has a diameter in a range of 100 nm to 200 nm.

46. The microparticle of claim 43, wherein the scattering element includes between 10 and 50 nanoparticles.

47. The microparticle of any one of claims 35-46, wherein the optical cavity comprises a microdisk.

48. The microparticle of any one of claims 35-46, wherein the active gain material comprises a semiconductor.

49. A method of generating laser light with high omnidirectionality comprising delivering one or more microparticles of claim 1 to a sample.

50. The method of claim 49, wherein the sample is a biological sample.

51. The method of claim 50, further comprising using the one or more microparticles as an optical probe of the biological sample.

52. A microdisk laser particle including light scattering elements configured to increase omnidirectionality by directing emission intensity of whispering gallery modes in the direction along a plane of the microdisk to a plane normal to the plane of the microdisk.
